(19) United States
(12) Patent Application Publication
(10) Pub. No.: US 2025/0151621 A1
(43) Pub. Date: May 8, 2025

(54) LIQUID CRYSTAL ELASTOMER WITH INTEGRATED SOFT THERMOELECTRICS FOR SHAPE MEMORY ACTUATION AND ENERGY HARVESTING

(71) Applicant: CARNEGIE MELLON UNIVERSITY, Pittsburgh, PA (US)

(72) Inventors: Mason Zadan, Pittsburgh, PA (US); Dinesh K. Patel, Pittsburgh, PA (US); Andrew Sabelhaus, Jamaica Plain, MA (US); Jiahe Liao, Stuttgart (DE); Anthony Wertz, Swissvale, PA (US); Carmel Majidi, Pittsburgh, PA (US)

(21) Appl. No.: 18/838,315

(22) PCT Filed: Feb. 14, 2023
(86) PCT No.: PCT/US2023/013067

§ 371 Date: Aug. 14, 2024

Related U.S. Application Data
(60) Provisional application No. 63/309,658, filed on Feb. 14, 2022.

(51) Int. Cl. H10N 10/856; H10N 10/81; H10N 10/852

(52) U.S. Cl. CPC H10N 10/856; H10N 10/81; H10N 10/852

(57) ABSTRACT

Stretchable and flexible thermoelectric devices may generally include a substrate having an array of semiconductors in electrical communication via a plurality of liquid metal interconnects, and coated on at least a portion thereof with opposing liquid crystal elastomer layers. The liquid crystal elastomer layers may be reaction products of a reaction mixture of a mesogenic group, a spacer, a crosslinker, and a photoinitiator. The liquid crystal elastomer layers may alternately heat and cool to achieve cyclical bending actuation when voltage is applied to the thermoelectric device. Methods of making and using the thermoelectric devices are also described.

### CROSS-REFERENCE TO RELATED APPLICATION

This application claims the benefit of U.S. Provisional Application No. 63/309,658, filed Feb. 14, 2022, the entire contents of which is incorporated herein by reference.

### GOVERNMENT RIGHTS

This invention was made with United States Government support under FA9550-16-1-0566 awarded by the U.S. Air Force and W911NF-18-1-0150 awarded by U.S. Army. The U.S. Government has certain rights in this invention.

### BACKGROUND

Liquid crystal elastomers (LCE) are a class of shape memory polymers composed of loosely crosslinked polymer networks that exhibit reversible shape change during transitions from nematic to isotropic phases. They have become increasingly popular as actuators for use in soft robotics, wearable computing and haptics, and shape morphing matter on account of their muscle-like work density and contraction strain and ability to be printed or patterned into a wide range of geometries. In most robotics and engineering applications, LCE-based actuators are stimulated thermally using an external heat source or electrically through Joule heating using an integrated wire or embedded network of percolating particles. Previous work has focused on heating LCEs primarily through Joule heating with many of these applications using liquid metal and wavy electronics as a heating element. However, a key limitation of these approaches is their reliance on open loop heating and passive cooling. This results in a limited ability to control the speed and profile of the LCE actuator response. In particular, actuation speeds can be slow and cooling times can take upwards of 5 times, 10 times, or even up to 50 times activation time to cool under ambient conditions to actuate back to the original state, with faster actuation shown to require longer cool down times. Accordingly, more efficient and/or cost-effective LCEs as well as methods of making the same may be desirable.

### SUMMARY

The present invention is directed to more efficient and/or cost-effective LCEs as well as methods of making and using the same.

According to the present invention there is provided a stretchable and flexible thermoelectric device comprising: a substrate comprising an array of semiconductors in electrical communication via a plurality of liquid metal interconnects, and coated on at least a portion thereof with opposing liquid crystal elastomer layers comprising a reaction product of a reaction mixture comprising a mesogenic group, a spacer, a crosslinker, and a photoinitiator, wherein the opposed liquid crystal elastomer layers alternately heat and cool to achieve cyclical bending actuation when voltage is applied to the device.

According to the present invention there is provided a single-degree-of-freedom robotic limb comprising a stretchable and flexible thermoelectric device comprising: a substrate comprising an array of semiconductors in electrical communication via a plurality of liquid metal interconnects, and coated on at least a portion thereof with opposing liquid crystal elastomer layers comprising a reaction product of a reaction mixture comprising a mesogenic group, a spacer, a crosslinker, and a photoinitiator, wherein the opposed liquid crystal elastomer layers alternately heat and cool to achieve cyclical bending actuation when voltage is applied to the device.

According to the present invention there is provided a liquid crystal elastomer-thermoelectric device walker comprising two stretchable and flexible thermoelectric devices oriented 90 degrees apart and connected at an end, wherein each stretchable and flexible thermoelectric device comprises a stretchable and flexible thermoelectric device comprising: a substrate comprising an array of semiconductors in electrical communication via a plurality of liquid metal interconnects, and coated on at least a portion thereof with opposing liquid crystal elastomer layers comprising a reaction product of a reaction mixture comprising a mesogenic group, a spacer, a crosslinker, and a photoinitiator, wherein the opposed liquid crystal elastomer layers alternately heat and cool to achieve cyclical bending actuation when voltage is applied to the device.

According to the present invention there is provided a method of making a stretchable and flexible thermoelectric device, the method comprising: providing a substrate configured to accept an array of semiconductors, embedding the array of semiconductors in the substrate; connecting the array of semiconductors in P-N configuration via a plurality of liquid metal interconnects, and applying a coating on at least a portion thereof with opposing liquid crystal elastomer layers comprising a reaction product of a reaction mixture comprising a mesogenic group, a spacer, a crosslinker, and a photoinitiator.

According to the present invention there is provided a method of using a stretchable and flexible thermoelectric device comprising: a substrate comprising an array of semiconductors in electrical communication via a plurality of liquid metal interconnects, and coated on at least a portion thereof with opposing liquid crystal elastomer layers comprising a reaction product of a reaction mixture comprising a mesogenic group, a spacer, a crosslinker, and a photoinitiator, the method comprising applying a voltage to the device.

### BRIEF DESCRIPTION OF THE FIGURES

The devices, systems, and processes described herein may be better understood by considering the following description in conjunction with the accompanying drawings; it being understood that this disclosure is not limited to the accompanying drawings.

FIGS. 1A-D include (A) a stretchable 90 semiconductor soft matter TED under deformation highlighting conformity of LM traces and 3D printed center layer. (B) Illustrations showing responsiveness of LCE shape memory polymer to heat. (C) LCE-TED soft limb during actuation with right side heating and left side cooling. Inset is a schematic diagram showing LM traces and semiconductors beneath the LCE layer. (D) Illustrations highlighting how the change in current direction across semiconductors reverses direction of actuation using only one input source.

FIGS. 2A-H include (A) temperature difference across a soft matter TEG vs open circuit voltage, confirming a linear relationship with small error. (B) resistance vs power and power density for varying temperature differentials. Inset is a circuit diagram for impedance matching. (C) Time vs temperature for varying currents on the heating side of a 90 semiconductor TEG. (D) Time vs temperature for varying currents on the cooling side for a 90 semiconductor TEG. (E) Graph of change in resistance for 1000 cycles at 25% compression highlighting no mechanical or electrical failure. Inset is a 44 semiconductor TEG at 25% compression in universal load frame. (F) strain vs load for 10000 compressive cycles. (G) Change in resistance for 10 cycles at 30% axial strain in universal load frame. (H) Stress strain curve for 10 cycles at 30% axial strain showing no mechanical failure or damage. Thermal Inset is a 44 semiconductor TEG heating properly after cyclic loading.

FIGS. 3A-F include (A) measurement of time vs stroke angle for a soft matter actuator running at 2.9 V followed by −2.9 V. (B) 99 cycle blocking force test at 1.7 V highlighting robustness and stability of actuator. (C) Voltage and current values for 5 representative cycles for the blocking force test. (D) comparison of cycles 2-5 and 95-98 highlighting high stability and no mechanical or electrical damage during a high cycle load. (E) Max blocking force test of time vs force at 2.9 V to determine a max force at break of 0.35 N. (F) comparison of voltage inputted during actuation through the Peltier effect (dotted line) and voltage outputted through the Seebeck effect during cool down cycles (solid line), highlighting regenerative energy recycling. FIG. 11 includes a chart of angular velocity of 60 semiconductor actuator at 2.9V corresponding to FIG. 3A.

FIGS. 4A-F include position control test of LCE-TED actuator prototypes. (A) The target robot limb pose is specified as a deflection angle, measured using a computer vision system. (B) Feedback control demonstrates low-error tracking of deflection angle, verified on two different actuator prototypes (1 and 2). (C-F) Walker demonstration of LCE-TED actuators. (C) Gait mechanics for one gait cycle of the two-legged soft walker. Specific actuation times are given in the example section. (D) Graph of energy harvesting from the front limb at the initial and final positions of the soft walker, highlighting the walker's ability to move over to a power source and passively generate voltage during hibernation. (E) Illustrations of initial vs final position away from the energy source corresponding to FIG. 4D. (F) Illustrations of an LCE exhibiting physical intelligence as it tracks towards a heat source and increases harvested voltage.

FIG. 5 includes TED fabrication steps: (5A-B) center layer and semiconductor substrate is printed using DLP printing process. (5C) P and N doped semiconductors are placed into the center layer and UV cured sealing them. (5D) A stencil is place overtop the center layer and EGaIn is airbrushed into the channels. (5E) the stencil is removed and the device is placed in the freezer. (5F) A UV curable ink is brushed on in a thin layer and cured at 365 nm for 12 mins. (5G) the process is repeated on the back side.

FIGS. 6A-C include illustrations of completed 90 semiconductor TED before LCE has been adhered.

FIGS. 7A and 7B include images of TEC-LCE actuator.

FIG. 8 includes a chart of external resistance vs current for varying temperature differentials generated by a 90 semiconductor TED as seen in FIG. 5. At a max temperature differential of 60° C. 38 mA was recorded at resistance of 1 n with current decreasing as resistance increased.

FIG. 9 includes a chart of external resistance vs voltage for varying temperature differentials generated from a 90 semiconductor TED. An increase in resistance corresponds to a voltage that approaches the open circuit voltage above 10 n.

FIGS. 10A and 10B includes illustrations of (A) 90 semiconductor TED heating at 1.75 A after 40 s and (B) 90 semiconductor TED cooling after 14 s.

FIG. 11 includes a chart of angular velocity of 60 semiconductor actuator at 2.9V corresponding to FIG. 3A.

FIGS. 12A and 12B include charts of step response test for tuning the proportional-integral (PI) controller for the LCE-TED soft limb. An 80% duty cycle PWM signal was applied to the forward-voltage gates of the H-bridge circuit for 55 s, and the constants a, K, and were measured for use with the first-order plus time delay (FOTD) tuning methods.

FIG. 13 includes a graph of position vs time for 5 cycles of the soft robotics walker. Yellow heating sections are represented by the gait mechanics in FIG. 4C. This is followed by a prolonged cool down time where the actuators passively regenerate energy.

FIG. 14 includes a chart of bending angle and harvested voltage of LCE-TED bending towards a heat source (see FIG. 4F) exhibiting phototropism for increased voltage.

FIG. 15 includes a table of 3D printing parameters for fabrication of soft and stretchable center layer.

FIG. 16 includes a comparison of Peltier heating and cooling for various currents. This test was conducted with the underside of the device in contact with water acting as a heat sink, and data recorded from the top side (n=3).

FIG. 17 includes comparison of Peltier heating and cooling data for ambient air conditions at 1.5 A (FIG. 2C-D) and bottom side in water (FIG. 16).

FIGS. 18A and 18B includes illustrations of actuator in initial vs actual position with relevant dimensions for figure of merit FoM calculations.

FIG. 19 includes a chart of input and output power for the regenerative energy harvesting test for one cycle.

FIG. 20 includes results of phototropism inspired energy harvesting test. The transducer was placed above and parallel to a heat source with voltage collected with and without the LCE layer, highlighting the physical intelligence of this system track towards a heat source and increase voltage output.

### DETAILED DESCRIPTION

This disclosure generally describes LCEs as well as methods of making and using the same. It is understood, however, that this disclosure also embraces numerous alternative features, aspects, and advantages that may be accomplished by combining any of the various features, aspects, and/or advantages described herein in any combination or sub-combination that one of ordinary skill in the art may find useful. Such combinations or sub-combinations are intended to be included within the scope of this disclosure. As such, the claims may be amended to recite any features, aspects, and advantages expressly or inherently described in, or otherwise expressly or inherently supported by, this disclosure. Further, any features, aspects, and advantages that may be present in the prior art may be affirmatively disclaimed. Accordingly, this disclosure may comprise, consist of, consist essentially or be characterized by one or more of the features, aspects, and advantages described herein. As used herein, the term “and/or” includes any and all combinations of one or more of the associated listed items.

All numerical quantities stated herein are approximate, unless stated otherwise. Accordingly, the term “about” may be inferred when not expressly stated. The numerical quantities disclosed herein are to be understood as not being strictly limited to the exact numerical values recited. Instead, unless stated otherwise, each numerical value stated herein is intended to mean both the recited value and a functionally equivalent range surrounding that value. At the very least, and not as an attempt to limit the application of the doctrine of equivalents to the scope of the claims, each numerical value should at least be construed in light of the number of reported significant digits and by applying ordinary rounding processes. Typical exemplary degrees of error may be within 20%, 10%, or 5% of a given value or range of values. Alternatively, and particularly in biological systems, the terms “about” refers to values within an order of magnitude, potentially within 5-fold or 2-fold of a given value. Notwithstanding the approximations of numerical quantities stated herein, the numerical quantities described in specific examples of actual measured values are reported as precisely as possible. Any numerical values, however, inherently contain certain errors necessarily resulting from the standard deviation found in their respective testing measurements.

All numerical ranges stated herein include all sub-ranges subsumed therein. For example, a range of “1 to 10” or “1-10” is intended to include all sub-ranges between and including the recited minimum value of 1 and the recited maximum value of 10 because the disclosed numerical ranges are continuous and include every value between the minimum and maximum values. Any maximum numerical limitation recited herein is intended to include all lower numerical limitations. Any minimum numerical limitation recited herein is intended to include all higher numerical limitations.

All compositional ranges stated herein are limited in total to and do not exceed 100 percent (e.g., volume percent or weight percent) in practice. When multiple components may be present in a composition, the sum of the maximum amounts of each component may exceed 100 percent, with the understanding that, and as those skilled in the art would readily understand, that the amounts of the components may be selected to achieve the maximum of 100 percent.

In the following description, certain details are set forth in order to provide a better understanding of various features, aspects, and advantages the invention. However, one skilled in the art will understand that these features, aspects, and advantages may be practiced without these details. In other instances, well-known structures, methods, and/or processes associated with methods of practicing the various features, aspects, and advantages may not be shown or described in detail to avoid unnecessarily obscuring descriptions of other details of the invention.

The terminology used herein is for the purpose of describing particular examples only and is not intended to be limiting. As used herein, the singular forms “a”, “an”, and “the” may be intended to include the plural forms as well, unless the context clearly indicates otherwise. The terms “comprises”, “comprising”, “including”, “having”, and “characterized by”, are inclusive and therefore specify the presence of stated features, elements, compositions, steps, integers, operations, and/or components, but do not preclude the presence or addition of one or more other features, integers, steps, operations, elements, components, and/or groups thereof. Although these open-ended terms are to be understood as a non-restrictive term used to describe and claim various aspects set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, described herein also specifically includes embodiments consisting of, or consisting essentially of, such recited compositions, materials, components, elements, features, integers, operations, and/or process steps. In the case of “consisting of”, the alternative embodiment excludes any additional compositions, materials, components, elements, features, integers, operations, and/or process steps, while in the case of “consisting essentially of”, any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on”, “engaged to”, “connected to”, or “coupled to” another element or layer, it may be directly on, engaged, connected or coupled to the other component, element, or layer, or intervening elements or layers may be present. In contrast, when an element is referred to as being “directly on”, “directly engaged to”, “directly connected to”, or “directly coupled to” another element or layer, there may be no intervening elements or layers present. Other words used to describe the relationship between elements should be interpreted in a like fashion (e.g., “between” versus “directly between”, “adjacent” versus “directly adjacent”, etc.).

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first”, “second”, and other numerical terms when used herein may not imply a sequence or order unless clearly indicated by the context. Thus, a first step, element, component, region, layer or section discussed below may be termed a second step, element, component, region, layer or section without departing from the teachings herein.

Spatially or temporally relative terms, such as “before”, “after”, “inner”, “outer”, “beneath”, “below”, “lower”, “above”, “upper”, and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures. As used herein, “top” means furthest away from the substrate, while “bottom” means closest to the substrate. Where a first layer is described as “disposed over”, “provided over”, or “deposited over” a second layer, the first layer is disposed further away from substrate. There may be other layers between the first and second layer, unless it is specified that the first layer is “in contact with”, “disposed on”, “provided on”, or “deposited on” the second layer.

The terms “on”, “appended to”, “affixed to”, “bonded to”, “adhered to”, or terms of like import means that the designated item, e.g., a coating, film or layer, is either directly connected to (superimposed on) the object surface, or indirectly connected to the object surface, e.g., through one or more other coatings, films or layers (superposed on).

A “film”, “layer”, or “coating” is defined as a thickness of some substantially continuous layer of material laid on, spread, or applied over a surface of another material, such as a substrate, in one or more applications. The material may be a single layer or as part of a multi-layer system. The material may be applied as a single layer. The material may be applied to an uncoated substrate. The material may be applied on top of layer as part of a multi-layer system. The material may form an intermediate layer or a top coat layer.

As used herein “stretchable” refers to the ability of a material, structure, device or device component to be strained without undergoing fracture such that it remains structurally and/or electrically intact when stretched to a length greater than its original natural length. For example, a stretchable material, structure, device or device component may undergo strain larger than 0.5% without fracturing, for some applications strain larger than 1% without fracturing and for yet other applications strain larger than 3% without fracturing. In another example, a thermoelectric stretchable material may not electrically or mechanically fail when stretched to strains above 50%. Many stretchable structures are also flexible, such as PDMS. Some stretchable structures (e.g., device components) are engineered to be able to undergo compression, elongation and/or twisting so as to be able to deform without fracturing. Stretchable structures include thin film structures comprising stretchable materials, such as elastomers; bent structures capable of elongation, compression and/or twisting motion; and structures having an island and bridge geometry. Stretchable device components include structures having stretchable interconnects, such as stretchable electrical interconnects.

As used herein, the terms “flexible” and “bendable” refer to the ability of a material, structure, device or device component to be deformed into a curved or bent shape without undergoing a transformation that introduces significant strain, such as strain characterizing the failure point of a material, structure, device or device component, such that it remains intact during bending or folding. A flexible material, structure, device or device component may be deformed into a curved shape without introducing strain larger than or equal to 5%, for some applications larger than or equal to 1%, and for yet other applications larger than or equal to 0.5% in strain-sensitive regions. Some, but not necessarily all, flexible structures are also stretchable. For example, a thin film of copper may be flexible but not stretchable. A variety of properties provide flexible structures (e.g., device components) of the invention, including materials properties such as a low modulus, bending stiffness and flexural rigidity; physical dimensions such as small average thickness (e.g., less than 100 microns, optionally less than 10 microns and optionally less than 1 micron) and device geometries such as thin film and mesh geometries. A flexible structure may comprise a curved conformation resulting from the application of a force. Flexible structures may have one or more folded regions, convex regions, concave regions, and any combinations thereof. For example, flexible structures may comprise a coiled conformation, a wrinkled conformation, a buckled conformation and/or a wavy (i.e., wave-shaped) configuration.

The stretchable electronic structure described herein may generally comprise a multilayer structure, including a structure wherein independently any of the substrate, liquid metal, and one or more layer(s) (and/or components of these) may be provided in a series of stacked layers, including layers and/or thin films that are provided in direct contact with each other in the series of layers or in a series having one or more intermediate layers (e.g., alloying layers, conducting layers, adhesive layers, contact layers, encapsulation layers, spacer layers, etc.) provided between layers of the series. The positioning of each layer of the multilayer structure may be selected to provide enhanced electrical and/or mechanical attributes or device functionality. The stretchable electronic structure may comprise a biocompatible material or a bioinert material. The stretchable electronic structure may comprise one or more of the polymers and elastomers described herein. The stretchable electronic structure may comprise a thickness up to 100 cm, up to 10 cm, or up to 1 cm. The device may have a thickness of at least 1 micrometer, at least 5 micrometers, at least 10 micrometers, at least 100 micrometers. The device may have a thickness from 1 micrometer to 1 meter, 5 micrometers to 10 cm. Each functional layer may be independently selected from a material and thickness sufficient to achieve its functionality in the multilayer structure. Each layer may be applied to a substrate once or multiple times. Each layer may be applied to any suitable dry film thickness. Each layer may be applied to a dry film thickness from 1 to 100 mm, such as from 1 to 75 mm, such as from 1 to 50 mm, such as from 1 to 40 mm, such as from 1 to 20 mm, from 1 to 10 mm, 1 to 100 micrometers, such as from 1 to 75 micrometers, such as from 1 to 50 micrometers, such as from 1 to 40 micrometers, such as from 1 to 20 micrometers, or even from 1 to 10 micrometers. Each layer may be cured by any suitable method, such as by heat curing, radiation curing, or by chemical curing, such as by heat curing. Each layer, when heat cured, may be cured at any suitable temperature.

The substrate may comprise a material having a surface that is capable of supporting a structure, including an electronic device or electronic device component. A structure that is “bonded” to the substrate refers to a portion of the structure in physical contact with the substrate and unable to substantially move relative to the substrate surface to which it is bonded. Unbonded portions, in contrast, may be capable of substantial movement relative to the substrate. The substrate may be planar, substantially planar, curved, have sharp edges, or any combination thereof.

The stretchable electronic structure described herein may comprise an encapsulation layer to completely or partially encapsulate one or more other device components such as the liquid metal and/or substrate. The structure may be completely encapsulated by, and in physical contact with, the encapsulation layer and/or substrate. For example, the encapsulation layer and/or substrate may encapsulate at least 50% of the liquid metal, at least 90% of the liquid metal, or all of the liquid metal. The encapsulation layer may partially or completely encapsulate the substrate. For example, the encapsulation layer encapsulates at least 50% of the substrate, at least 90% of the substrate, or all of the substrate. The encapsulation layer may effectively encapsulate the device from the surrounding environment. The encapsulation layer may be periodically reapplied, such as daily, weekly, monthly, or annually, to facilitate long term use. A plurality of encapsulation layers may be applied, including encapsulation layers having different compositions for different functionality. For example, one encapsulation layer may provide waterproofing and another encapsulation layer may provide durability. In this manner, the encapsulation layer may be a composite cover layer to achieve better functional outcome. The encapsulation layer may be functionally similar to the adhesive layer, contact layer, and/or spacer layers. For example, the encapsulation layer may comprise an adhesive layer that binds to skin. In another example, the encapsulation layer may comprise a spacer layer that separates one or more layers of the multilayer structure.

The stretchable electronic structure described herein may comprise a wearable substrate supporting the stretchable substrate, the liquid metal or both. The wearable substrate may comprise a fabric. The wearable substrate may facilitate administration or donning of the device to a portion of the body by which the device is being worn, for example, by providing net mechanical properties and/or physical dimensions of the device to allow effective handling, transfer and/or deployment to the body interface in a manner that does not damage or modify the properties of the other components of the device (e.g., substrate, liquid metal or other components). Transfer layers may also function as sacrificial layers that are at least partially removed upon administration to the body, for example, via dissolution or delamination (e.g., peel back) processes.

The transfer substrate may directly or indirectly contact the stretchable substrate. The transfer substrate may be bound to the stretchable substrate via one or more adhesive layers. The transfer substrate may comprise a removable substrate, wherein the transfer substrate is partially or completely removed after the device establishes conformal contact with the body. For example, the removable substrate may comprise a dissolvable substrate, wherein the removable substrate is partially or completely dissolved after the device is provided in contact with the body, for example via washing or rinsing with one or more solvents (e.g., water). The removable substrate may be configured to be separated from the stretchable substrate after administration, for example, via a delamination process.

The transfer substrate may comprise a bioinert or biocompatible material, for example, to minimize or avoid inflammation or unwanted immune responses upon administration of the device to a body in a biological environment. The transfer substrate may comprise a polymer layer having a thickness from 1 micrometer to 100 mm. The transfer substrate may have a composition and physical dimensions that allowed the device to be handled and/or administered by hand, for example, during a surgical procedure.

The stretchable electronic devices described herein may comprise a controller in communication with a stretchable electronic circuit comprising the liquid metal. The controller may be useful to provide device control, signal processing, and/or measurement analysis functionality. The controller may receive input signals from the stretchable electronic circuit that serves the basis of closed-loop control of the electronic device, for example, providing real-time adjustment of sensing and actuation. The controller may provide closed-loop control of sensing and/or actuation based on signals received from the stretchable electronic circuit corresponding to measurements of one or more properties.

For example, the controller may be configured to provide an output signal to the stretchable electronic circuit, receive an input signal from the stretchable electronic circuit, or to provide an output signal to the stretchable electronic circuit and receive an input signal to the stretchable electronic circuit. As used herein, “in communication” refers to a configuration of devices or device components such that a signal may be exchanged, and includes one way communication and two way communication between the controller and the stretchable electronic circuit. The controller may be in electrical communication or wireless communication with the stretchable electronic circuit. The output signal may provide an input to the stretchable electronic circuit so as to control actuation or sensing. For example, the output signal may provide a sensing or actuation parameter from the controller to the stretchable electronic circuit, such as, a parameter relating to the timing of a measurement or actuation, the magnitude of a sensing or actuation variable (e.g., voltage, current, power, intensity, temperature, etc.). The input signal may provide a measurement parameter from the stretchable electronic circuit to the controller, such as a measurement parameter corresponding to a time, voltage, current, impedance, intensity, power, or temperature. The input signal may provide a measurement parameter corresponding to a plurality of voltage measurements, current measurements, electromagnetic radiation intensity or power measurements, temperature measurements, pressure measurements, acceleration measurements, movement measurements, chemical/physical concentration measurements, time measurements, position measurements, acoustic measurements or any combination of these. For example, the controller may receive and analyze the input signal from the stretchable electronic circuit and generate an output signal that controls or provides a sensing or actuation parameter(s) to the stretchable electronic circuit, for example via a closed-loop control algorithm that adjusts the sensing or actuation parameter(s) based on one or more measurements. A wide range of controllers may be useful in the present devices and methods, including a microprocessor, microcontroller, digital signal processor, computer or fixed logic device. Controllers of this aspect include implantable controllers, controllers that are administered along with the stretchable electronic circuit and controllers that are ex vivo.

The stretchable electronic devices described herein may generally comprise devices such as integrated circuits, imagers or other optoelectronic devices. Electronic devices may also refer to a component of an electronic device such as passive or active components such as a semiconductor, interconnect, contact pad, transistors, diodes, LEDs, circuits, etc. Devices described herein may be useful in one or more of the following fields: collecting optics, diffusing optics, displays, pick and place assembly, vertical cavity surface-emitting lasers (VCSELS) and arrays thereof, LEDs and arrays thereof, transparent electronics, photovoltaic arrays, solar cells and arrays thereof, flexible electronics, micromanipulation, plastic electronics, displays, pick and place assembly, transfer printing, LEDs, transparent electronics, stretchable electronics, and flexible electronics.

The present invention is directed to methods to integrate LM-based circuits with traditional electronic materials and components for increased functionality of flexible and stretchable circuits. The combination of conventional rigid electronics, flexible and stretchable electronics with deterministic geometries and LM-based electronics on a single flexible circuit may provide the merits and functionality of each system on a single device. Rigid electronic component may be used to provide functionalities (e.g., power management), a sensing modalities (e.g., orientation, range, acceleration, magnetic field strength, speed, pressure, altitude, deformation, humidity sensing), communication (e.g., radio frequency (RF), WiFi, BLUETOOTH), and/or on-board digital processing. Flexible and stretchable electronics may provide soft and stretchable sensing (e.g., pressure, strain, tactile), communications (e.g., antennas), analog circuit elements (e.g., capacitors, resistors, inductors and diodes), and/or soft and stretchable interconnects (i.e., wiring) among the rigid and flexible elements to maintain electrical functionality under mechanical deformation (e.g., bending, twisting, stretching or compression).

The liquid metal may comprise any conductive metal material that is liquid at room temperature, such as 1-30° C., 15-25° C., 15-30° C., or 20-25° C. For example, the liquid metal comprises a conductive material that is liquid at a temperature from −20° C. to 40° C. The liquid metal may comprise one or more of a boiling point greater than 1300° C., a melting point less than 0° C., less than −5° C., less than −10° C., or less than −15° C., a vapor pressure less than 10.sup.−8 Torr (at 500° C.), a density of 6.44 g/cm³ (at 20° C.), insoluble in water or organic solvents, a viscosity of 0.0024 Pa\tilde{ }s (at 20° C.), a thermal conductivity of 16.5 Wm⁻¹K⁻¹, an electrical conductivity of 3.46×106 S/m (at 20° C.), a surface tension of 0.535-0.718 N/m (at 20° C.), and a specific heat capacity of 296 Jkg⁻¹. The liquid metal may comprise indium (In), silicon (Si), tin (Sn), germanium (Ge), bismuth (Bi), zinc (Zn), tellurium (Te), lead (Pb), gallium (Ga), aluminum (Al), arsenic (As), lithium (Li), or combinations thereof. For example, the liquid metal may comprise a metal alloy comprising gallium and copper. The liquid metal may comprise EGaIn and/or Galistan (68.5% Ga, 21.5% In, and 10% Sn, by weight). The liquid metal may be a metal alloy consisting essentially of gallium, indium, and copper and, optionally, tin.

The one or more intermediate layers may each independently comprise platinum (Pt), copper (Cu), gold (Ag), lead (Pb), niobium (Nb), palladium (Pd), platinum (Pt), nickel (Ni), chromium (Cr), manganese (Mn), vanadium (V), tin (Sn), aluminum (Al), tantalum (Ta), iron (Fe), and combinations thereof. For example, an intermediate metal adhesion layer may comprise chromium and an intermediate metal alloying layer may comprise copper. The metal adhesion layer may comprise at least one of copper, gold, silver, aluminum, and tin. The metal adhesion layer may comprise silver nanoparticles, nanodots, or nanopowders, such as, an ink comprising metal nanoparticles, such as silver nanoparticles, for example.

The stretchable elastomer layer may comprise an elastomer that is colorless and transparent when viewed under visible light. “Elastomer” refers to a polymeric material which can be stretched or deformed and return to its original shape without substantial permanent deformation. Elastomers may undergo substantially elastic deformations. Useful elastomers include those comprising polymers, copolymers, composite materials or mixtures of polymers and copolymers. Elastomeric layer refers to a layer comprising at least one elastomer. Elastomeric layers may also include dopants and other non-elastomeric materials. The elastomer may be comprise thermoplastic elastomers, styrenic materials, olefenic materials, polyamides, polyimides, polyvinylchlorides, polyolefins, polyethylenes, polypropylenes, polybutylenes, ethylene-propylene copolymers, polyisobutyrates, polystyrenes, acrylonitrile-butadiene-styrene resins, polycarbonates, poly acrylic and methacrylic acid resins, polyethylene terephthalates, polyurethanes, epoxy resins, silicone resins, polyester resins, alkyd resins, acrylonitrile polymers, polyesteramides, ethylene-vinyl acetate copolymers, natural rubber (e.g., latex), synthetic rubbers, polyisoprene (e.g., natural or synthetic), and block copolymer elastomers, such as styrene-ethylene-butylene-styrene elastomer (SEBS) and combinations thereof. The elastomer may comprise silicones (e.g., polydimethylsiloxane; soft urethanes (e.g., polyurethane elastomer); acrylate polymers (e.g., acrylic elastomers); and/or fluoropolymers (e.g., perfluoroelastomer). The stretchable elastomer layer may comprise one of a stretchable silicon layer and a stretchable fluoropolymer layer. For example, the stretchable elastomer layer may comprise one of polydimethylsiloxane and polytetrafluoroethylene.

As generally used herein, “polymer” refers to a macromolecule composed of repeating structural units connected by covalent chemical bonds or the polymerization product of one or more monomers, often characterized by a high molecular weight. The term polymer includes homopolymers, or polymers consisting essentially of a single repeating monomer subunit. The term polymer also includes copolymers, or polymers consisting essentially of two or more monomer subunits, such as random, block, alternating, segmented, graft, tapered and other copolymers. Useful polymers include organic polymers or inorganic polymers and may be in amorphous, semi-amorphous, crystalline or partially crystalline states. Cross linked polymers having linked monomer chains are particularly useful for some applications. Polymers useable in the methods, devices and device components include, but are not limited to, plastics, elastomers, thermoplastic elastomers, elastoplastics, thermostats, thermoplastics and acrylates. Exemplary polymers include, but are not limited to, acetal polymers, biodegradable polymers, cellulosic polymers, fluoropolymers, nylons, polyacrylonitrile polymers, polyamide-imide polymers, polyimides, polyarylates, polybenzimidazole, polybutylene, polycarbonate, polyesters, polyetherimide, polyethylene, polyethylene copolymers and modified polyethylenes, polyketones, poly (methyl methacrylate, polymethylpentene, polyphenylene oxides and polyphenylene sulfides, polyphthalamide, polypropylene, polyurethanes, styrenic resins, sulfone based resins, vinyl-based resins, rubber (including natural rubber, styrene-butadiene, polybutadiene, neoprene, ethylene-propylene, butyl, nitrile, silicones), acrylic, nylon, polycarbonate, polyester, polyethylene, polypropylene, polystyrene, polyvinyl chloride, polyolefin or any combinations of these.

Liquid crystal elastomers (LCE) have attracted tremendous interest as actuators for soft robotics and shape morphing matter due to their robust mechanical and shape memory properties. However, LCE actuators typically respond to thermal stimulation through active heating and passive cooling, which make them difficult to control in robotics applications. In this paper we combine LCE with soft, stretchable thermoelectrics to create transducers capable of electrically controlled actuation and thermal-to-electrical energy conversion. The thermoelectric layers are composed of n-type and p-type bismuth telluride (Bi₂Te₃) elements embedded within a 3D printed elastomer matrix and wired together with eutectic gallium-indium (EGaIn) liquid metal interconnects. This layer is covered on both sides with LCE, which alternately heat and cool to achieve cyclical bending actuation in response to voltage-controlled Peltier activation of the thermoelectric. Moreover, the thermoelectric layer can harvest energy from thermal gradients between the two LCE layers through the Seebeck effect, allowing for regenerative energy harvesting between actuation cycles. The present invention may have the advantage of active thermoelectric heating and cooling of LCE through three demonstrations. First, closed-loop control of the transducer is performed in order to rapidly track a changing actuator position. Second, a pair of transducers are used as limbs of a soft robotic walker that is capable of walking towards a heat source and harvesting energy. The present invention may be characterized by phototropic-inspired autonomous deflection of the limbs towards a heat source, demonstrating an additional method to increase energy recuperation efficiency for soft systems.

There have been recent efforts to improve the speed and control of LCE actuators through novel methods of stimulation, though most of these introduce significant mechanical design challenges for robotics. Compared to external convection heating and Joule activation, faster and more controlled LCE response can be achieved by pumping hot and cold fluid through embedded microfluidic channels or by utilizing compressed air. However, this leads to the need for bulky heating units and liquid pumps for actuation. Other approaches for actuating LCEs have included electromagnetic (EM) radiation, including visible, microwave, and infrared light (IR). However, these methods are unrealistic for robust autonomous robotic motion as these robots must be in range of directional EM emitters, often times with line of sight, which often times do not have adequate precision needed for controlled robotic actuation. Approaches with magnetic actuation have also been tried, but these require large external magnets and are susceptible to potential interference issues with the environment such as metal around where the robot is navigating through. While promising, these approaches are still limited in their ability to enable robust and repeatable heating and cooling for controllable actuation and are not all compatible with lightweight mobile or wearable robotic devices.

A second challenge with LCE actuators is the low energy efficiencies associated with the existing methods of stimulation. Heating through Joule activation requires high input power (about 1-10 W) over long periods of time (about 10-100 s) to heat LCE above their nematic-to-isotropic transition temperatures. Moreover, during intracycle cooling, this energy is lost through convection cooling. Likewise, although convection heating and EM-based actuation methods can increase actuation speeds, they are also susceptible to inefficiency on account of indiscriminately directing energy over large volumes. These prohibitive properties make it difficult for LCE-based actuators to become viable options when compared to other actuation modalities. Moreover, such challenges are not limited to LCEs and are also observed in other thermally-activated shape memory materials such as nickel-titanium shape memory alloys (SMA), which suffer from low energy efficiencies of 1-2%. A possible approach to increase the efficiency is recycling some of the otherwise-wasted thermal energy back into the actuator or host device. One of the future potentials and advantages of soft robotic systems is the ability to recovery energy that is momentarily stored within soft materials and actuators that would otherwise go unused. In the case of LCEs, the ability to recover energy from residual heat and thermal gradients could contribute to improved energy efficiency and longevity of the host electronic device or robotic system.

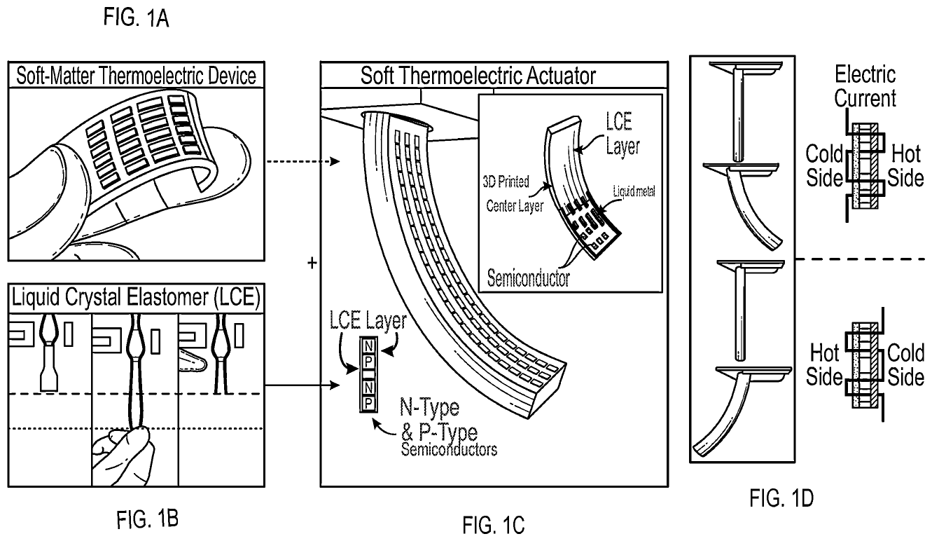

The present invention seeks to simultaneously address both challenges by combining LCEs with a thin thermoelectric layer that is soft, stretchable, and conforms to LCE deformation. The thermoelectric device (TED) layer is composed of n-type and p-type bismuth telluride (Bi₂Te₃) microcubes that are wired together with eutectic gallium-indium (EGaIn) liquid metal interconnects and embedded within a 3D printed elastomer matrix (FIG. 1A). This approach to create TEDs that are soft and elastic builds on recent research that has focused on combining Bi₂Te₃ with elastomers and liquid metals to create thermoelectric generators that are flexible and stretchable. This TED architecture doubles as a Peltier heating/cooling device to control the contraction of the LCE layers and an energy generator that uses the Seebeck effect to convert thermal gradients into electricity. In the Peltier mode, it can be used as thermal stimuli for LCE, which exhibits the shape memory response presented in FIG. 1B. This thermoelectric layer is then placed between two pre-strained pieces of LCEs (FIG. 1C) to create an ‘LCE-TED’. When one side of the LCE-TED contracts during heating, it induces uniform bending of the transducer. Reversing the flow of current causes that same side to subsequently cool and the opposite side of the device to heat up, resulting in bending in the opposite direction (FIG. 1D). By incorporating a soft and stretchable thermoelectric device, both high and low temperatures can be applied to the LCE layers at the same time with only one electrical input. By placing the thermoelectric device in the center of the actuator, this ensures that heat is both being delivered effectively to the contracting side of LCE as well as cooling the opposite side actively.

Through a series of soft robotics demonstrations, the present invention may significantly improve adoption of LCEs in practical applications. First, closed-loop position control of our LCE-TED shows fast and accurate tracking due to active cooling. Prior applications of feedback to LCE-based robotic actuators are few, and focuses on sensing capabilities. Most are only proof-of-concept, are relatively slow, and either lack full pose feedback for the robot or are nonspecific about the feedback procedure. In each case, the lack of cooling (i.e., a negative control input) limits the ability to apply traditional control analysis techniques. Other types of antagonistic thermoelectric actuators can be modeled with a bidirectional control input; however, these require either careful techniques to avoid overheating, external cooling hardware, or highly advanced constitutive models. The present invention may be configured to tracking control using a theoretically-grounded feedback procedure to reduce and/or eliminate each of these drawbacks.

Second, a soft robot comprising two of actuators according to the present invention show the LCE-TED locomoting to a heat source and harvesting energy while stationary. Although simple in design, this two-limbed walker demonstrates the potential for creating soft robotic systems that can harvest some of their electrical power from energy in the environment. Lastly, to further increase voltage harvesting potential, the present invention may be characterized by “physical intelligence” of this transducer to autonomously orient itself closer to a heat source, which allows for more electricity to be generated through the Seebeck effect. This feature is loosely inspired by phototropism, in which a plant responds and moves towards a light source. Together, these demonstrations show significant promise for robots built from soft thermoelectric liquid crystal elastomer actuators according to the present invention.

The present invention may comprise a TED layer with an array of n-and p-type Bi₂Te₃ semiconducting chips that are wired in series using EGaIn liquid metal traces. The chips are embedded inside an elastomer matrix that is 3D printed using a digital light processing (DLP) method and sealed with UV curable ink.

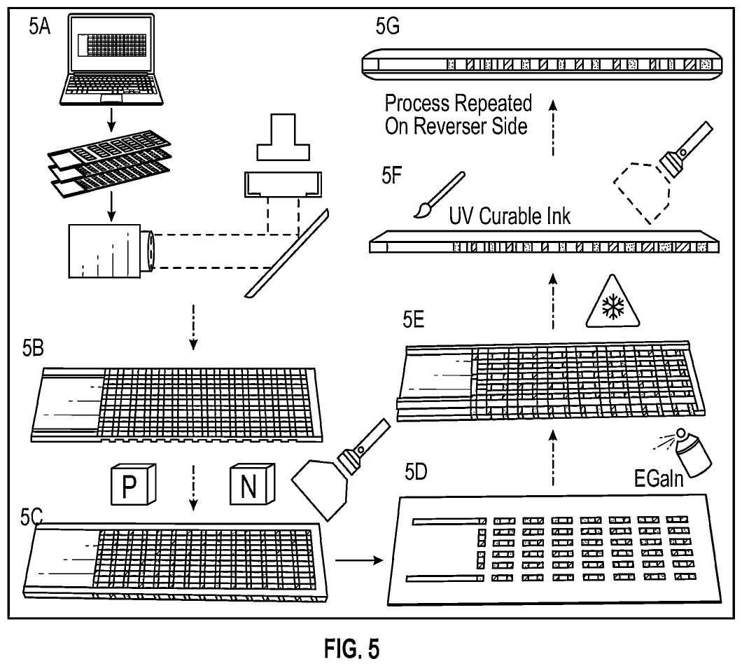

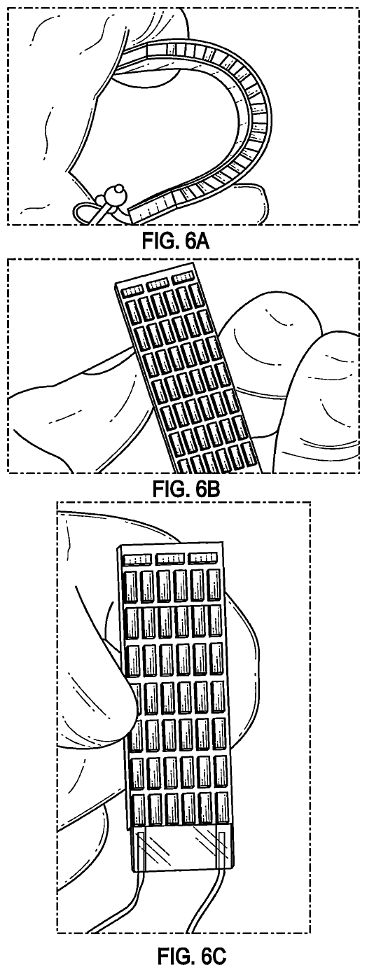

The soft TED enables operation of both the Peltier and Seebeck effect and is mechanically compatible with layers of LCE placed on the top and bottom surface. FIGS. 5A-G depicts steps for device fabrication. Further, details on 3D printing, fabrication parameters, and semiconductor properties can be found in the examples section and additional images of fabricated devices are shown or presented in FIGS. 6A-C. The TEDs are made with a maximum of 90 semiconducting chips (1.4×1.4×1.6 mm) in 6 rows of 15 with overall active dimensions of 43.0×14.5×3.4 mm.

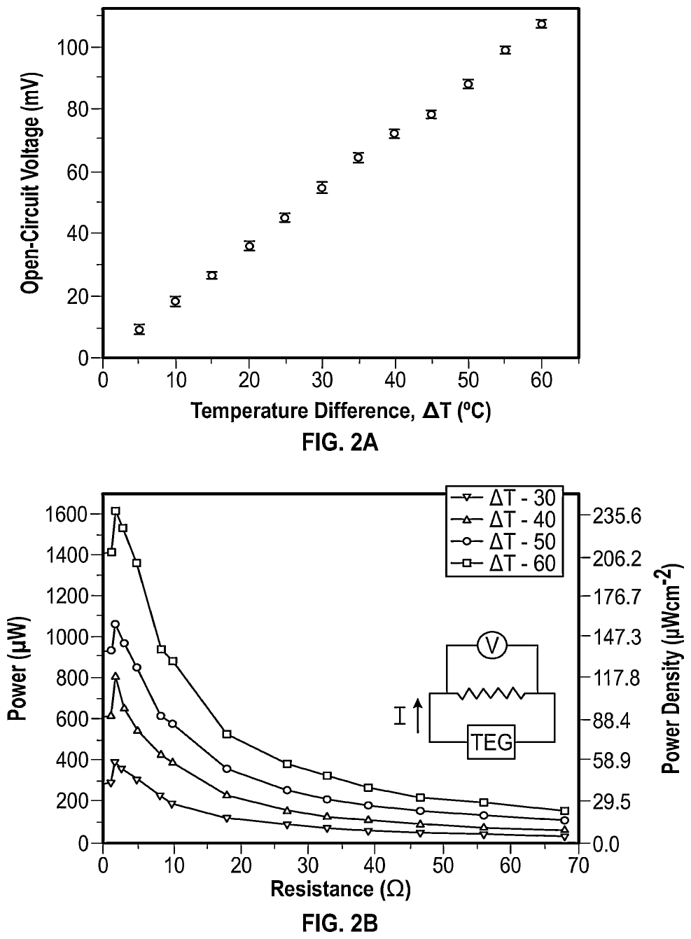

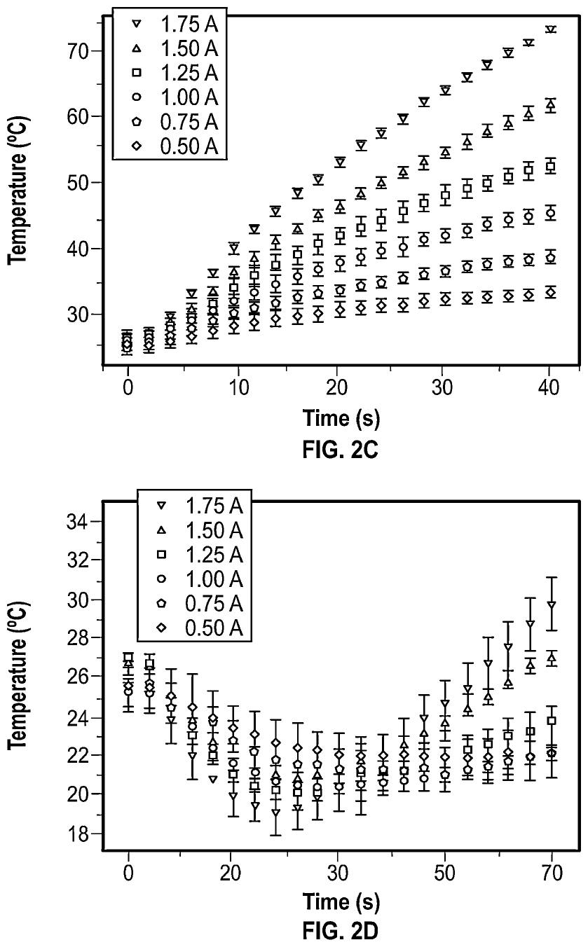

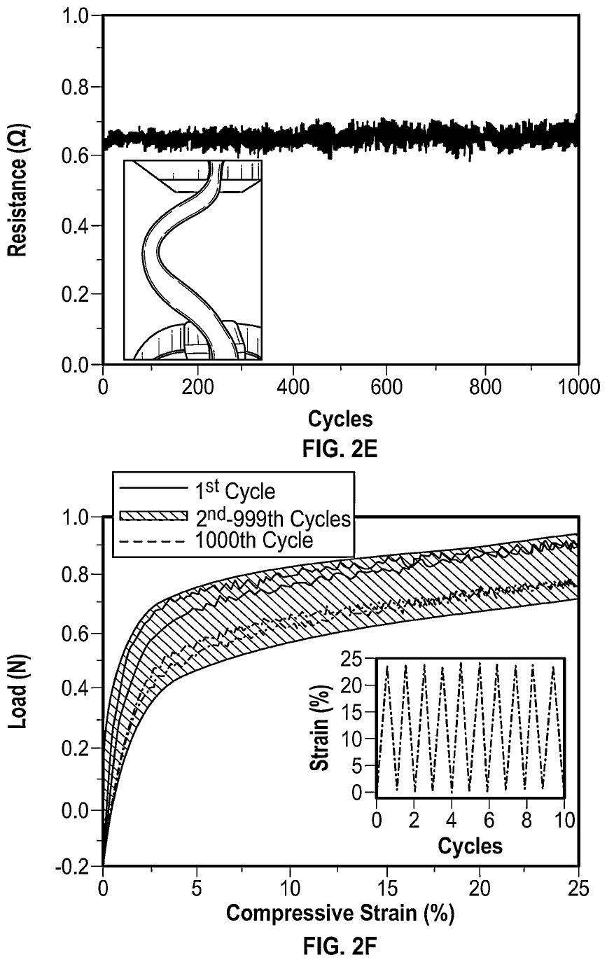

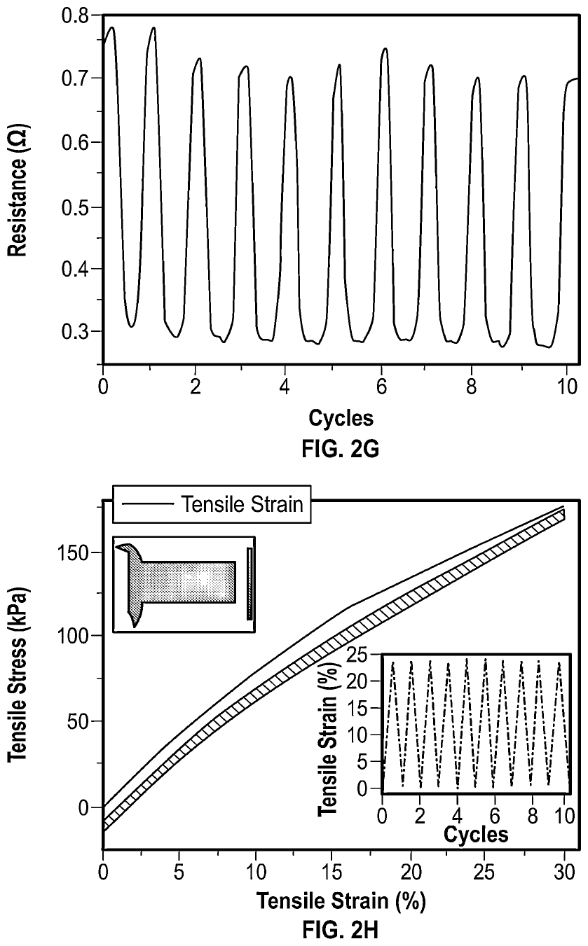

Experimental measurements for energy harvesting through the Seebeck effect are presented in FIG. 2A-B. The voltage V generated by a temperature difference ΔT is estimated as V=nαΔT, where n is the number of n-type/p-type semiconductor pairs and α is the Seebeck coefficient of the bismuth telluride. FIG. 2A shows the open-circuit voltage generated from changing temperature differentials across the TED. A linear relationship was found between temperature difference and voltage in line with the established relationship of V=nαΔT. At ΔT=30° C. and 60° C., voltages of 54.7±2.0 mV and 107.1±0.7 mV was recorded as an increase in temperature corresponds to larger charge buildup across junctions. While voltages are low, they are in the range needed for voltage boosting to power small microcontrollers (LTC3108 Analog Devices).

By impedance matching the internal resistance of the thermocouple arrays with an external resistor, power can be optimized for the highest possible power output when the device is in contact with a heat source. FIG. 2B inset gives a diagram of the TEG and external resistor in parallel with multimeter setup recording the voltage output.

By recording voltage output (V_{TEG}) and varying the external resistance (Rₑₓₜ) the power output is determined by

$$P = \frac{{V}_{TEG}^{2}}{{R}_{ext}} .$$

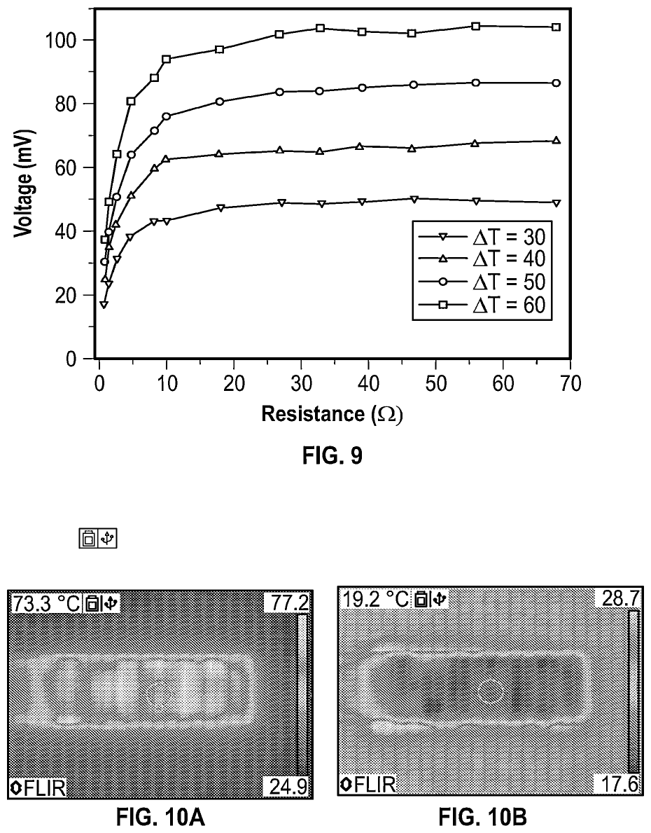

FIG. 2B gives external resistance vs power and power density for temperature differentials of ΔT=30° C. to 60° C. Peak power was recorded at an external resistance of 1.5Ω which is in line with the recorded internal resistance at room temperature of about 1.5Ω indicating that impedance matching is taking place as expected. At ΔT=60° C., a max power of 1.61 mW and 236 μWcm⁻² was recorded which corresponds to a 32.7 mA current (FIG. 9). This is a about 2.75 power density increase over previous work at the same temperature differential.

When resistance is plotted against voltage (FIG. 10), an increase in external resistance corresponds to a sharp increase followed by leveling off of voltage around 10Ω. Voltages begin to approach open circuit voltage at these higher resistor values as the impedance increases. For instance, at ΔT=60° C. V_{oc}=107.1±0.7 mV (FIG. 2A) and with an external resistance of 67.9Ω a similar voltage of 104 mV was recorded (FIG. 10). This has been shown before as an increase in impedance from the external parallel resistor leads to a voltage output approaching an open circuit voltage. In this case voltage saturates at an external resistance of around an order of magnitude above internal resistance.

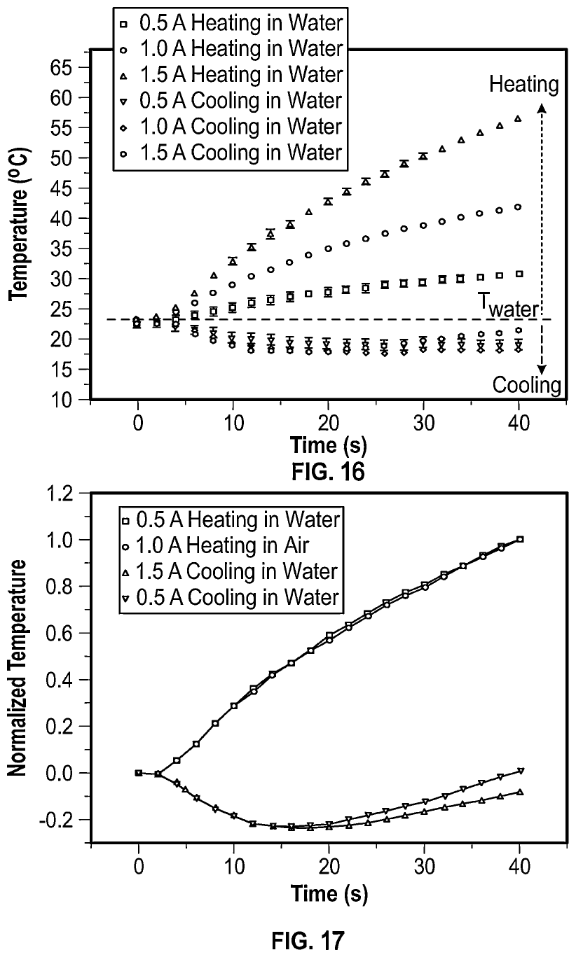

Characterization of the Peltier effect for voltage-controlled heating/cooling is presented in FIG. 2C-D. By applying a current across thermocouples in series, temperature differentials are created at the junctions as the thermocouple alternates from forward bias to reverse bias. This Peltier effect allows us to create the uniform and fast heating and cooling that is needed to give effective heat output and absorption to the LCE surrounding the actuators. To better understand these characteristics, the Peltier effect for LCE actuation was characterized by recording heating and cooling curves for the TEDs at varying currents. Increasing current increases the rate of temperature increase for heating curves as expected (FIG. 2C). At 1.75 A the TED generated 73.4±0.3° C. at 40 s (FIGS. 10A, 10B, and 16) with a power draw of 5.5 W while at the lower current of 0.5 A at 40 s with a power draw of 0.4 W, the heat generated was 33.5±0.8° C. with a leveling off of temperature increase in this time range.

While an increase in current corresponded to an increase in temperature, the relationship between cooling and current was more complex. As there is no thermal management or heat sink used during these tests, heat tends to bleed across the 3D center layer. This is seen from the cooling data (1.75 A) (FIG. 2D) as the temperature drops quickly initially from an initial temperature of 25.6±1.0° C. to 19.1±1.1° C. at 14 s (FIGS. 10A, 10B and 16), followed by a sharp increase to 29.8±1.4° C. at 40 s giving the maximum cooling effect of 6.5° C. Having a local minimum followed by sharp temperature increase is less prominent in lower currents where less heat is generated on the opposite ends of the semiconductors with less energy transferring as quickly across. At 0.5 A the cooling side is 22.7±1.2° C. at 14 s and 22.0±1.1° C. at 40 s with both values within standard error of each other. This needs to be considered when actively cooling the TEGs as too high of a current will not necessarily lead to a lower temperature

In order to confirm that the thermoelectric layer could perform effectively under the stresses of repeated use as actuators and energy harvesters without degrading electrically or mechanically, cyclical bending and axial strain tests were conducted. FIG. 2E gives internal resistance data for 1000 cycles at 25% compression with the dotted line representing the value of initial resistance. The data showed excellent stability for use in actuators during bending. An image of the device in the compressed state is given in the inset. After 1000 cycles no mechanical or electrical failure was observed.

In addition, no significant increase in resistance was found after 1000 cycles indicating the 3D printed polymer center layer and LM traces are deforming without affecting contact resistance with the semiconductors during actuation. Under these loading conditions plastic deformation occurs with changes in stress strain curves between the first (solid line) and one thousandth (diagonal line) cycles (FIG. 2F). It is also unclear why the load of the final cycle is higher than the lowest sets of cycles in the greyed-out region. Hysteresis was shown to occur intra-cycle as expected but in no way impacting actuator performance.

During operation in a soft actuator or robotic system, these TEDs may exhibit very little to no axial strain. Nonetheless, we demonstrate the ability of the soft thermoelectric device to be cyclically loaded to 30% uniaxial strain for 10 cycles (FIG. 2G). Resistance dropped from about 0.7Ω at 0% strain to about 0.3Ω at 30% strain. No damage or trends in resistance were detected during these tests. In addition, no mechanical or electrical failure occurred. This decrease in resistance may be caused by a decrease in contact resistance between semiconductors and LM traces from transverse compression during axial loading. This should not be an issue for the actuators as very little axial strain is occurring during actuation. After the test was completed, voltage was applied across the terminals of the device. The device functioned well with no semiconductors failing to generate heat (FIG. 2H thermal inset). Mechanical stability was observed after the first cycle of axial loading as seen in FIG. 2H. There is limited hysteresis during loading for the other nine cycles showing mechanical stability of the 3D printed components under extreme conditions.

By placing photoinitiated pre-strained LCE onto each side of the TED, the present invention may be used to create a flexural actuator in which the opposing LCE layers are simultaneously heated and cooled. For fabricating actuators, the LCE was prestrained to 80% and UV cured and adhered to each side of the TED (FIG. 1C and FIG. 8).

Actuator angle and force output were characterized to better highlight the actuator characteristics and inform controls and robotic applications given in the next section. Results indicated that these actuators have a high angle of stroke, can generate significant force for an actuator made of soft components, and repeatable and controllably deliver that same force output as a function of time cyclically for a high number of repetitions. As opposed to Joule heated actuators with one direction of motion per voltage input, these TED actuated soft muscles can operate in positive and negative angular domains above and below zero degrees bending angle using only one input.

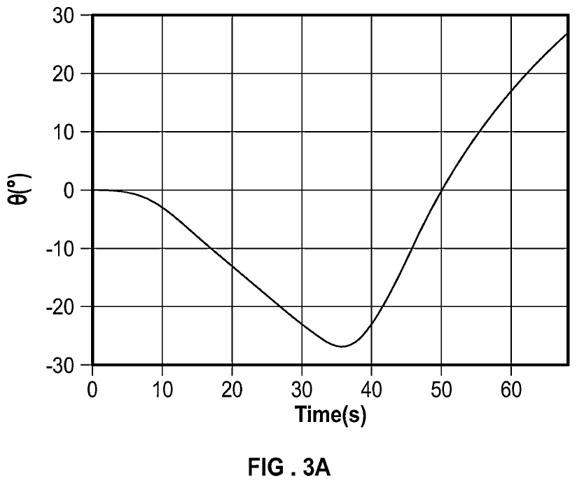

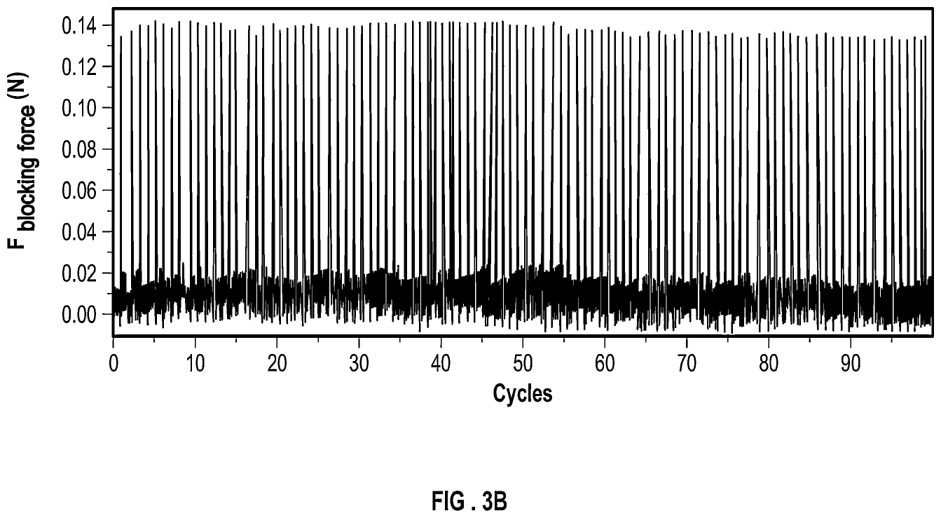

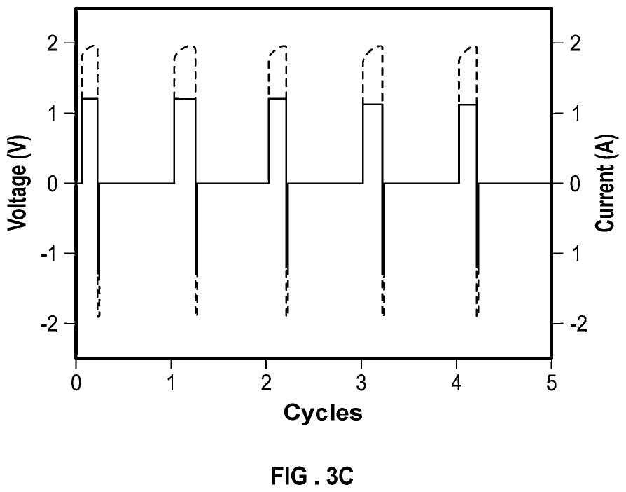

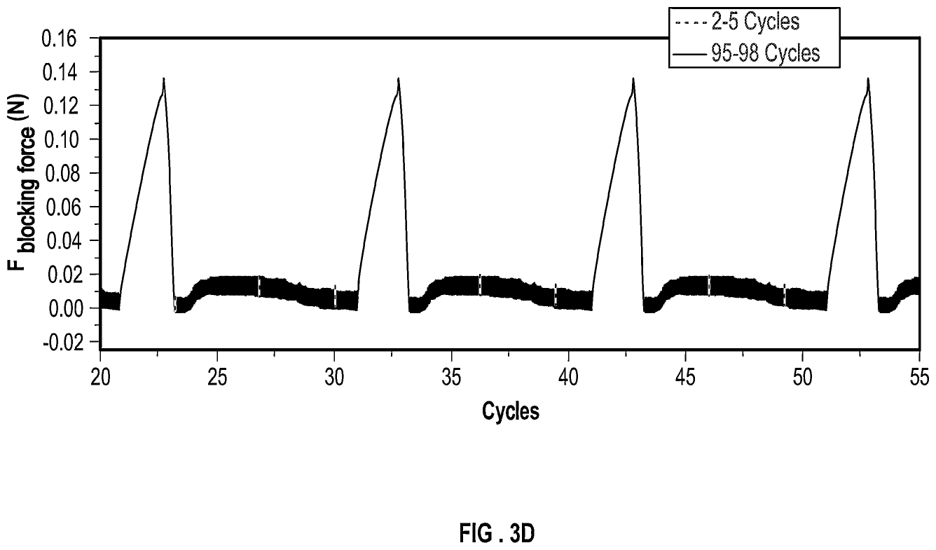

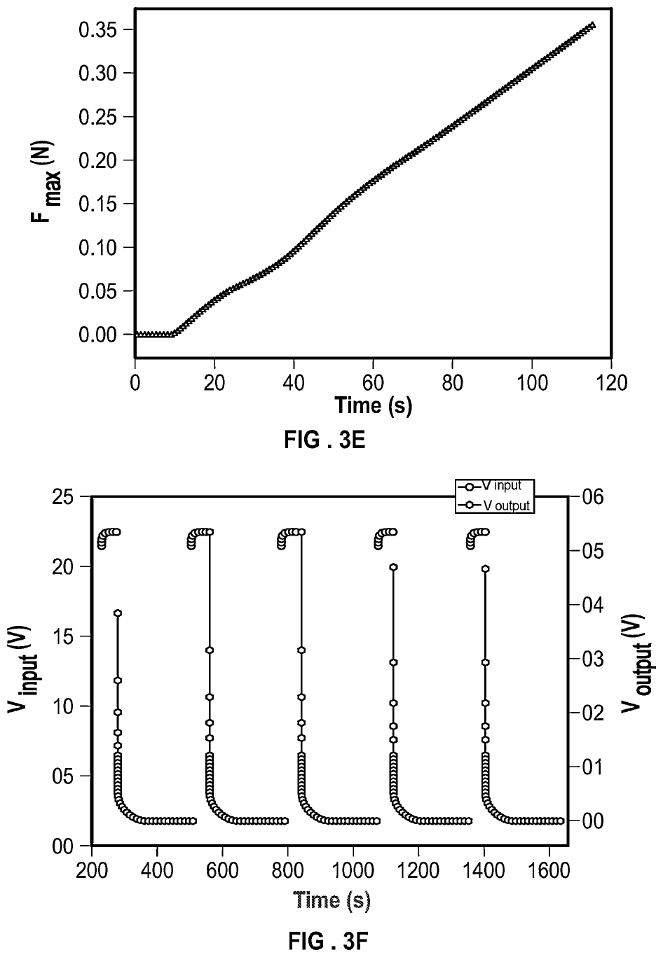

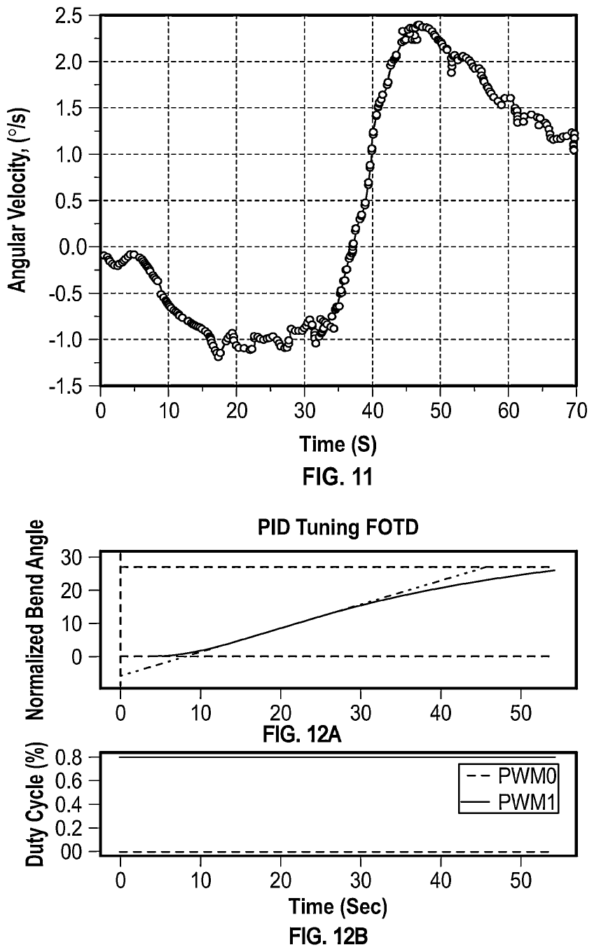

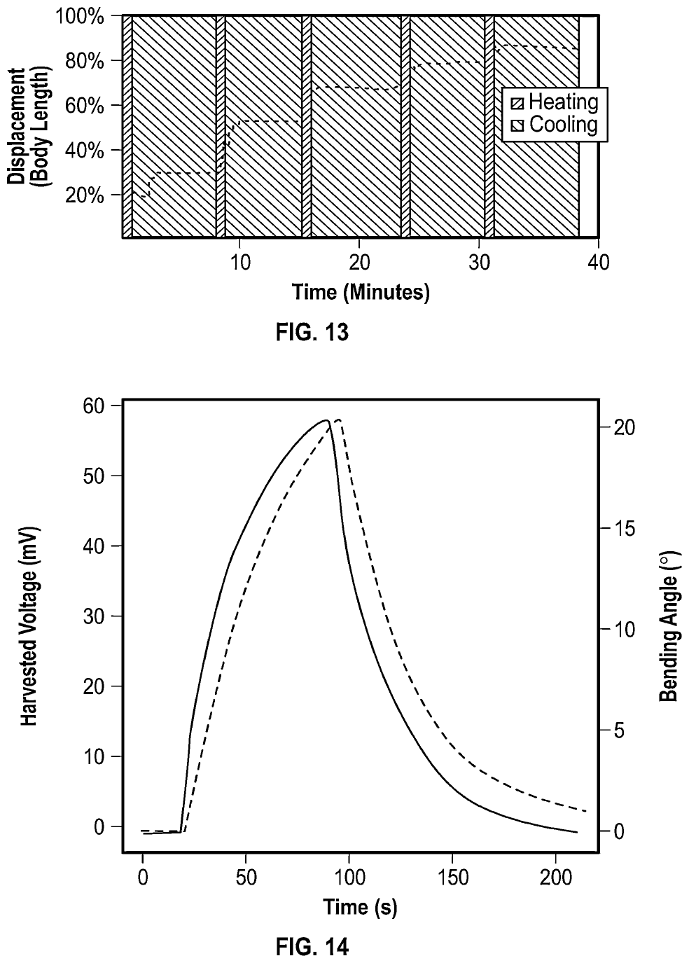

By reversing the input voltage from positive to negative the actuator can both actively heat and cool the opposing surfaces at the same time, reversing the direction of actuation. A representative cycle is shown in FIG. 1D with time versus angle results shown in FIG. 3A. With a positive voltage of 2.9 V applied followed by −2.9 V max angles of 27° and −27° are reported. The maximum angular velocity recorded during testing was 2.5°/s (FIGS. 11 and 17). The ratio of time from 0° to 27° and 27° back to 0° is 1:0.43 for one cycle. This multidirectional actuation and active cooling is an order of magnitude faster compared to actuation cycles (1:10) of previous single input joule heated actuators that require ambient air cooling. As there is a defined relationship between temperature and contraction, these actuators operate better when running warm. This may explain the steeper slope in actuation in the negative direction when negative voltage is applied. The LCE has already warmed up due to some thermal bleeding from the heated side onto the cooling side as seen in FIG. 2D. This along with elastic potential energy stored accounts for the faster actuation upon voltage reversal. The first of the 99 blocking force cycles in FIG. 3B also highlights this characteristic as the initial cycle is the only force output that varies significantly from the others and represents a warmup cycle.

FIG. 3bB shows a plot of time vs force output for the LCE actuator blocking force test for 99 cycles. Using an H-bridge circuit the device was actuated for 95 s at 1.7 V into the load cell, 22 s at −1.7 V in reverse until a 0° angle, and 380 s of cooling time at 0 V for 99 cycles. The FIG. 3C graphs time vs voltage and current for five representative cycles. While power source voltage is constant along with current, voltage across the actuator varies from 1.5-2.0 V to −1.5 to −2.0 V to 0 V per cycle as varying semiconductor resistances inside the device and across the pins of the H-bridge MOSFETs (used to reverse current directions) affect voltage. With an average max force output of 0.138 N and a small standard error of 0.003 N for 98 cycles, high repeatability, stability, and robustness are shown.

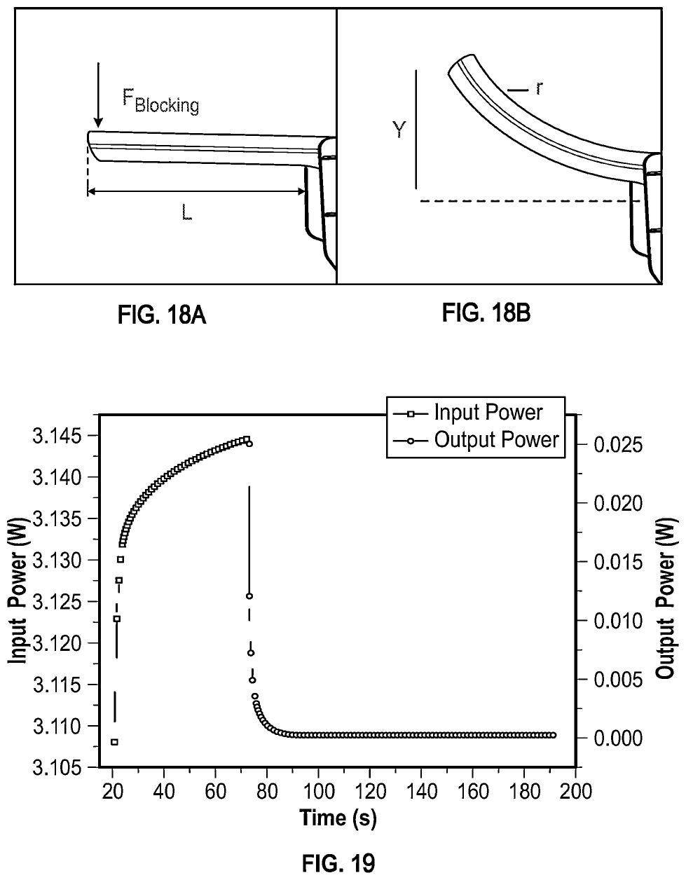

To highlight force output stability and consistency, the cycles 2-5 are compared to cycles 95-98 in FIG. 3D. These force output curves are almost identical with max output along with heating and cooling slopes being indistinguishable between initial and final cycles. Intracycle, the importance of running these actuators “warm” for faster actuation is again shown as only 23% of the positive actuation time is required to return to 0° bending angle. By running this actuator at a higher voltage of 3.2 V we obtained a max force output of 0.35 N at break confirming high force output for a soft robotic muscle. Compared to commercially available 1.37 mm diameter shape memory alloy, Flexinol nitinol coiled wire (Dynalloy inc), the force outputs are comparable with a heating and cooling force output of 0.39 N and 0.17 N respectively. By defining a figure of merit (FoM) for this device at Ue/(Ue+Ut) where Ue is the elastic energy and Ut is the thermal energy, the FoM of 0.0008 for one cycle at 3.2 V. Further, information is shown in FIGS. 18A and 18B regarding the “Transducer Efficiency”.

In between actuation cycles, a portion of the heat applied to the system during Peltier heating can be converted back into voltage through the Seebeck effect. Much like regenerative energy harvesting from induction motors during braking, in which induction motors double as energy harvesters when torque is applied to the motor, the LCE-TED actuators have similar characteristics correspondingly through electrothermal instead of kinetic energy conversion. This unexpected characteristic was tested for five cycles, inputting heat into the system through Peltier heating for 35 s at 2.2 V followed by recording the voltage output during a 4 minute cool down as the actuator moved back to the rest position. Results are shown on FIG. 3F, with the left y-axis showing voltage input and the right y-axis showing generated voltage. The maximum generated voltage of 0.53 V was recorded. Voltage drops quickly and heat transfers across the system as it approaches a steady state. By analyzing one cycle at 2.7 V across the transducer for 50 s and 0 V for 6 min of energy harvesting (FIG. 19), we can determine the efficiency of applied vs generated energy to be η=0.03%. While this efficiency is not high enough to increase the range of the actuator in a meaningful way, we introduce this as a proof of concept and hope it spurs further investigation of efficient energy recovery methods that can be used for soft actuators. Potential methods to improve efficiency include decreasing the thermal resistance between the semiconductors and LCE layer to guarantee better contact before the temperature differential across the entire device degrades due to heat conduction. This unexpected characteristic introduces a new approach for more energy efficient soft robotic actuators in a new more efficient direction.

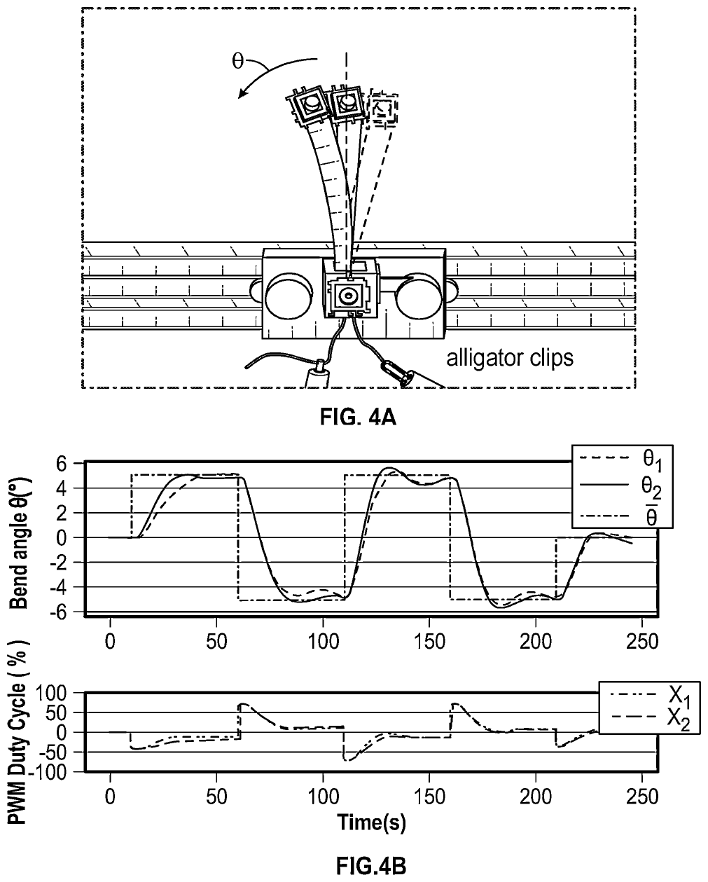

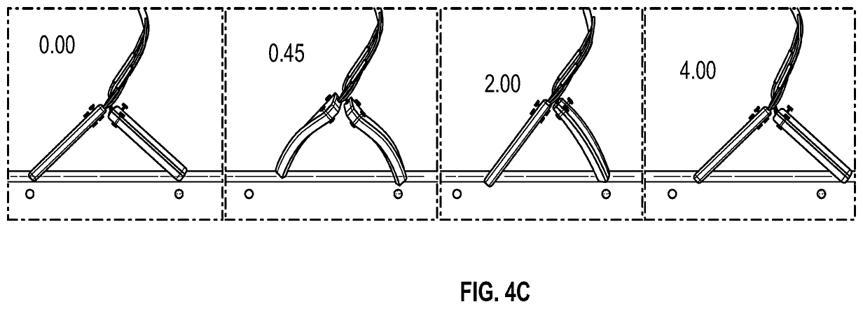

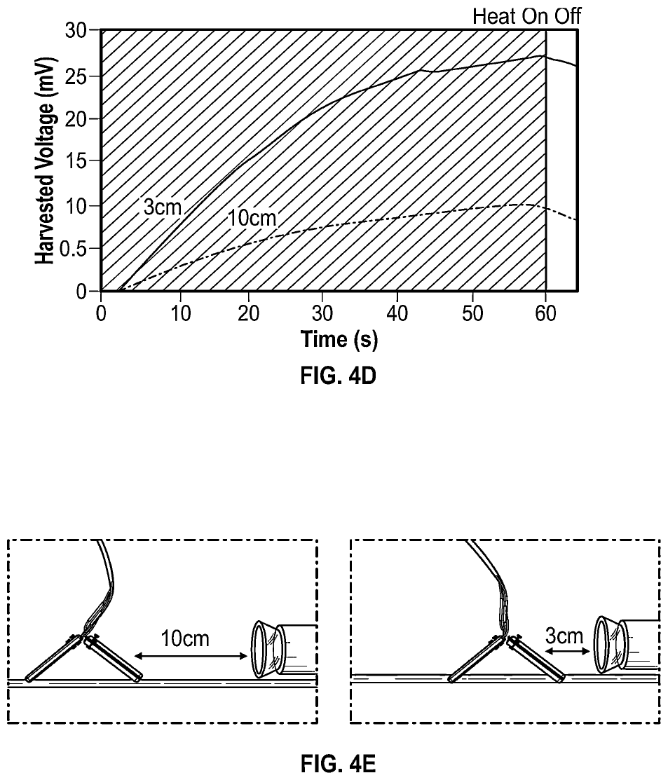

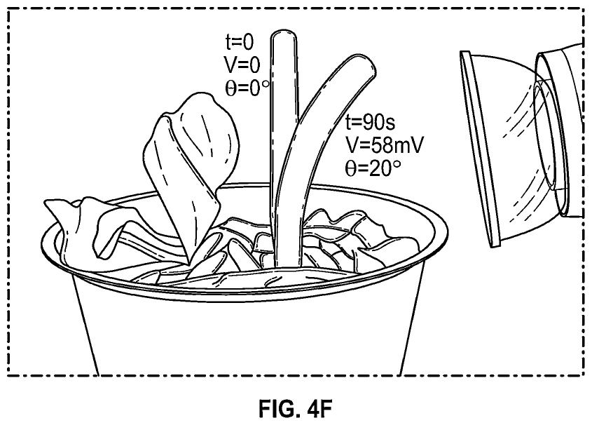

A position-control feedback test was performed to track deflections of the soft LCE-TED actuator, which may be considered to be a single-degree-of-freedom robot limb. Using the feedback procedure discussed in the examples section, the limb held alternating angles of +5° or −5° for 50 seconds each (FIG. 4A). This response was verified using two different soft limb prototypes that were tested with the same control system. Results show that the actuator can quickly switch between positive and negative angles (FIG. 4B), as anticipated from the characterization tests. Even though the control system never applies the full 100% duty cycle power, the limb still reaches its desired angle after only approximately 20 s. This would not be possible with passive cooling alone. The position error reaches less than 0.5° after settling, which is more than sufficient for most soft robotics applications.

To demonstrate the use of these transducers in a robotic system, a LCE-TED walker according to the present invention may be capable of walking towards a heat source and harvesting energy. The walker is composed of two LCE-TED limbs that are oriented 90° apart and connected at the ends. At the distal end where the limb makes contact with the ground, an angled and jagged copper shim is adhered in order to enable anisotropic friction and allow the walker to move in a forward direction. By reversing the voltage direction during actuation, we induced forward movement as the limbs contracted and expanded, first pulling together and then pushing apart. Additional gait information is given in the materials and methods section. FIG. 4C presents images of a representative gait cycle.

The task planned for this robot was to move itself over to an energy source, in this case a heat lamp, and generate continuous electricity. Distance between the limb and energy source is key to overcoming the heat loss of air's low thermal conductivity. Initially, the voltage output of the front limb at a distance of 10 cm away from the heat source was recorded. The walker then actuated over to the heat source in order to record a higher voltage output (FIGS. 4C-E and 13). After re-recording the voltage, a much higher voltage output when the limb is closer at 3 cm to the heat lamp was recorded (FIGS. 4C-E). When reaching the heat source, the soft walker enters a “hibernation” state during which time it can generate power indefinitely from a heat source. Without wishing to be bound to any particular theory, it is believed that as the limb generated voltage, the limb closest to the heat lamp begins to heat up and actuates in response to the ambient heating. This limb bending causes closer to the heat lamp (see FIG. 4E).

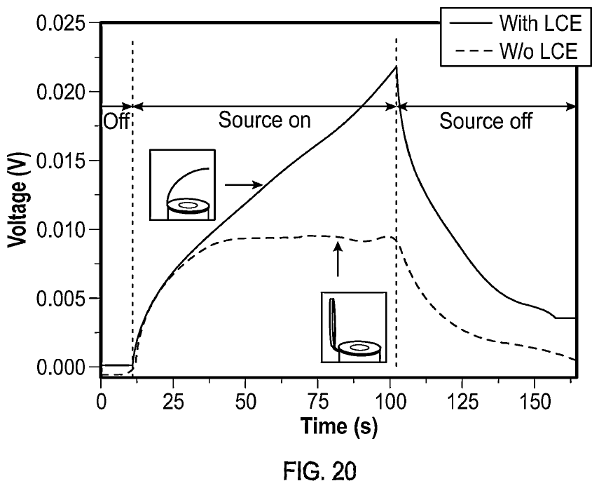

For the soft walker demonstration, the limb closest to the heat source may be configured to bend in response to the ambient heating and pull the walker closer to the heat lamp. Without wishing to be bound to any particular theory, it may be inferred that passive “physical intelligence” of the transducer by which it will autonomously move towards the energy source and improve its ability to generate voltage. This effect, which loosely resembles phototropism and heliotracking SMPs, is further presented in FIG. 4F. By placing a soft limb vertically near a heat source and applying no voltage to the limb, the soft transducer autonomously bends towards the heat source. See FIG. 14. In doing so, it decreases the distance between the thermoelectric layer and heat source, thereby causing an increase in the amount of electricity that is generated (FIG. 18B (right). When the heat source is turned off, the voltage drops as the limb moves away from the heat source and returns to its naturally straight configuration (see FIGS. 4F and 14). Comparison tests were conducted with and without the LCE layer in which the heat source is placed adjacent to the base of the actuator and oriented so that heat is directed upwards (parallel to the actuator). These measurements show an improvement in voltage output when LCE is incorporated into the limb. Without wishing to be bound to any particular theory, it is believe that this is because LCE actuation will cause the limb to autonomously bend toward the heat source and experience a larger surface area over the heat source leading to a larger temperature differential. Unlike the LCE-integrated limb, the passive limb does not bend and exhibits a voltage output plateau of 10 mV after 50 s of exposure to the heat source. In contrast, the autonomously responsive limb with LCE exhibited a greater than 2× voltage output with a maximum voltage output of 22 mV (see FIG. 20). This energy harvesting demonstration shows the physical intelligence of the LCE-thermoelectric transducer and suggests the potential for future soft robotic systems to generate and consume energy from their surroundings in between actuation cycles or during periods of hibernation (e.g., sleep mode) or low-power operations.

This work has demonstrated the use of 3D printed deformable thermoelectric devices in LCE actuators to enable both active heating and cooling of LCEs along with energy harvesting. By controlling heating and cooling actively, multidirectional actuation can be controlled with one input improving actuation times over ambient cooling by an order of magnitude. With both heating and cooling, we have shown a practical feedback control example, with a rapid bidirectional response and no external cooling hardware, suitable for integration into soft robots.

Additionally, this work has introduced the concept of soft actuators with intrinsic energy harvesting capabilities for environmental energy harvesting along with regenerative thermal recycling. The latter allows for the recycling of otherwise wasted thermal energy and is analogous to regenerative braking used in induction motors for electrical vehicles. By taking the exploiting temperature gradients in nature or by exploiting internal temperature differentials between the LCE layers, the Seebeck effect converts thermal energy into electricity that can be used for subsequent actuation cycles. The present invention illustrates the potential of LCE-TED actuators in a tethered two legged-walker demonstration in which the walker moves to a heat source to generate voltage. Lastly, these limbs demonstrate a form of physically intelligence in their ability to autonomously reconfigure themselves to increase the amount of energy harvested from an external heat source.

Future areas of improvement and current limitations center around thermal management. These actuators still have a prolonged cooldown time in between cycles that can take over 3× the actuation time at low voltages (FIG. 3B) and up to 6.5× when larger activation voltages are used. Each LCE sheet of the LCE-TED limb is not independent of the other, with heat transferring across the 3D printed elastomer separation layer during prolonged actuation. This can lead to heat saturation within the actuator due to poor heat transfer through convection cooling and can produces high stresses at both interfaces, leading to delamination from the TED layer. One solution is increasing the bonding strength without increasing structural rigidity through stronger adhesives. Separately, decreasing thermal conductivity between the LCE sheets by taking full advantage of 3D printing for creating thermally insulating metamaterials may be another promising direction.

While these approaches would allow the LCE-TED based limbs to operate for longer cycles, they do not address the inter-cycle cooldown time limitations. For this, focus must be shifted to a new generation of high thermal conductivity deformable heat sinks to aid in convective cooling. Liquid metal embedded elastomer (LMEE) composites have been shown to have high mechanical compliance along with high thermal conductivities. Previous work has shown LMEE composite's potential in TED based systems for thermal management. Further incorporating such material architectures and manufacturing methods could lead to further improvements in LCE-TED performance. Lastly, the transducers may be integrated into a soft robot to realize the potentials of LCE-TED limbs more fully. Untethered soft robotic platforms are a potential candidate to more fully develop the energy harvesting and controls potential introduced here.

### EXAMPLES

The LCEs as well as methods of making and using the same described herein may be better understood when read in conjunction with the following representative examples. The following examples are included for purposes of illustration and not limitation.

### Example 1

Materials and Methods

Elastomeric resin composition: The elastomeric resin used for 3D printing center layer comprises of 49.02 wt. % of epoxy aliphatic acrylate (EAA, Ebecryl 113, Allnex USA), 49.02% of aliphatic urethane acrylate (AUD, Ebecryl 8413, Allnex, USA) and 1.96% TPO (Diphenyl(2,4,6-trimethylbenzoyl)phosphine oxide, Genocure TPO, RAHN USA Corp.) as the photo-initiator. TPO was dissolved in elastomeric monomers on hot water bath 86° C.

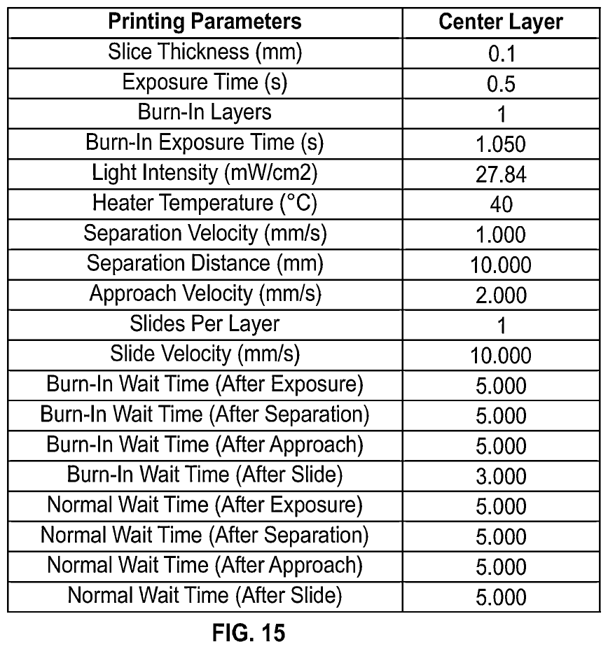

3D printing: 3D printing was performed using a DLP-based 3D printer (PicoHD@27,Asiga). This printer operates by a top-down DLP system with a digital mirror device (DMD) and a UV-LED light source operating at 385 nm. The printer was maintained at 40° C. during printing and each layer was irradiated for 0.5 s and layer thickness was 100 μm. The detailed printing parameters are included in supplementary section, FIG. 15. The printed structures were sonicated with isopropyl alcohol (IPA) for 3 min to remove uncured resin.

Thermoelectric device fabrication: The center layer (53×14×1.6 mm), which acts as a substrate for the LM channels and semiconductors, was printed using a DLP 3D printer (FIG. 5, step 5A). The center layer consists of 1 mm wide and 0.4 mm deep channels for LM interconnects and holes for semiconductors (FIG. 5, step 5B). Depending on the desired configuration 44-90 1.4×1.4×1.6 mm 99.99% purity Bi₂Fe₃ semiconductors (Wuhan Xinrong New Materials Co., Ltd.) are placed into 1×1×1.6 mm holes. This is followed by a post curing in a UV chamber (CL-1000 Ultraviolet Crosslinker, UVP) for 3 minutes on each side to ensure a tight seal between substrate and semiconductors, mitigating LM shorting (FIG. 5, step 5C). A Stencil (polyester plastic McMast-Carr) is then placed on the substrate and EGaIn is airbrushed (Master G22) into the channels for 30 seconds (FIG. 5, steps 5D-E). The device is then placed in a freezer at −30° C. solidifying the EGaIn traces below their melting temperature of 15.5° C. The same UV curable ink used for the center layer is brushed onto the exposed LM traces using a paint brush covering them in a thin layer and UV cured for 12 mins at λ=365 nm (Warson R838) (FIG. 5, step 5F). This process is repeated on the back side with thin copper tape leads being attached before airbrushing (FIG. 5, step 5G). The TED dimensions of the active part are 43.0×14.5×3.4 mm with a 28% fill factor by surface area. Fill factor may be determined by dividing the surface area of the semiconductors by the surface area of the active surface area (e.g., the surface area of the TED). More images of completed devices are available in FIGS. 6A-C.

LCE fabrication: 10.957 g of RM257 monomer (1,4-Bis-[4-(3-acryloyloxypropyloxy) benzoyloxy]-2-methylbenzene) (Wilshire Technologies; 95%) is dissolved into 3.40 g toluene (Sigma-Aldrich) at 80° C. for 20 minutes. Once cooled for 5 minutes 3.026 g EDDET (2,2′-(ethylenedioxy) diethanethiol) (Sigma-Aldrich), 0.488 g PETMP (pentaerythritol tetrakis (3-mercaptopropionate)) (Sigma-Aldrich), 0.077 g HHMP ((2-hydroxyethoxy)-2-methylpropiophenone) (Sigma-Aldrich), and 0.038 g DPA (dipropylamine) (Sigma-Aldrich) are mixed into the monomer solution and vortexed mixed for 1 minute. The mixture is then degassed for 1 minute and poured into 11×2×0.2 cm molds, with each mold creating enough LCE for one actuator. Samples oligomerize for 12 hours at room temperature in a fume hood followed by 12 hours in a vacuum oven (Across International) at 80° C. and 508 mm of Hg to evaporate the toluene. The LCE is uniaxially strained to 80% and UV light (UVP, UVL-56 handheld UV lamp) is applied to crosslink for 30 minutes at 365 nm and 6 W programming in a reversible pre-strain of 39-45%. When pre-strained the LCE strips are 1.1 mm thick and a 400 micron thick layer of Sil-poxy is then used to adhere the strips to each side of the TEG.

Thermoelectric Testing: Open circuit voltage data was collected for three cycles at room temperature with the TEG placed on a hot plate with a 200 g mass ensuring even contact. Thermoelectric testing was conducted without the LCE layer to better understand the TEDs themselves. Peak voltage being recorded as temperature differentials can degree quickly. Power data was recorded by measuring voltage in parallel to the external resistor from the circuit given in the inset of FIG. 2B. The TEG was placed on a hot plate with a 200 g mass ensuring even contact. Max voltage in parallel was recorded for various resistor values. In between cycles the TEG was cooled to ambient temperatures. For Peltier cycles data was recorded for three passes for 40 s with a 90-semiconductor device being used. Temperatures were recorded using a thermal camera (FLIR C2) along with all tests being conducted at room temperature. The device was cool into between cycles.

Mechanical and Blocking Force Testing: All force and cyclical loading tests were conducted in a universal load frame (Instron 5969). Mechanical tests were run on a 44 semiconductor TEG modified to accept clamps for the universal load frame. Blocking force tests were performed on a 60 semiconductor actuator with a 10 N load cell placed right above with the actuator placed parallel to the ground. The LCE TED actuated into the load cell determining force output. An Arduino microcontroller and power source along with an H-bridge of power MOSFET was used to switch current directions for the blocking force test.

Feedback control test: The feedback control test uses a hardware platform wherein the LCE-TED is clamped to a rigid frame, connected to an electronic circuit in an H-bridge configuration of power MOSFET transistors, and receives positive or negative voltage via two pulse-width-modulation (PWM) signals. The nominal applied voltage across the device is calibrated to 2.9 V at the start of each test. A microcontroller changes the applied power by setting the positive/negative PWM duty cycle at time k, i.e., u(k) E [−1, 1], mapping negative duty cycles to the PWM connected to the “reverse” signal of the H-bridge. Two computer vision markers are placed on the test setup, one on the clamp and one at the tip of the actuator, so that a camera (Intel, Real Sense) measures the deflection angle of the soft limb (θ(k)) in real time. Our control system takes a desired angle (θ−(k)) and uses proportional-integral (PI) feedback to specify PWM duty cycle as a function of the position error e=O−O, i.e., u(k) Kₚ e(K)+E^{k}/ₜ₌₀Kᵢe(t) Δt. The controller gains Kₚ and Kᵢ were estimated using various PI tuning rules from the literature.

Feedback Control Design: The proportional-integral (PI) feedback controller was tuned using a control input that cools the device—a negative voltage. With heating alone, a PI controller would attempt to apply a negative control input and would incorrectly saturate at 0V.

Tuning of a PI controller was performed using the time domain step response method1,where a constant control input was applied and various properties of the resulting trajectory are used to estimate the proportional (Kₚ) and integral (Kᵢ) constants. A 80% duty cycle input step, representative of the actuator during its aggressive operation was used, mapped to the PWM that controlled the “forward” signal of the H-bridge circuit.

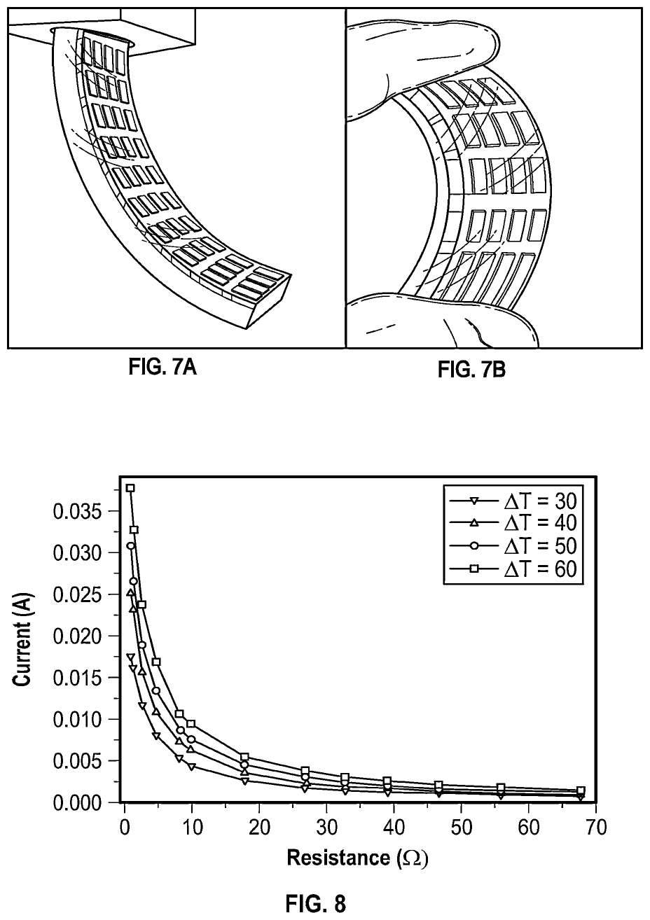

FIG. 7 shows the step response alongside the three tuning constants that are used in the first-order plus time delay method. Note that the approximated time delay, r, is very large (approx. 8.5 sec), making high-performance control challenging without an accurate system model.

The three methods used to estimate feedback gains from these step response parameters. These included the Zeigler-Nichols method and its two modifications to include the settling value of the step response, K (FIG. 7). Averaging the estimated gains gave Kₚ=0.096, Kᵢ=4×10⁽⁻²⁾. Executing the controller with these gains showed significant oscillations, primarily due to the time delay. After adjustments by hand, our final controller used Kₚ=0.08, Kᵢ=2×10⁽⁻⁶⁾, representing significantly lower integral control.

Finally, note that although our PI controller could potentially saturate above 100% or below −100% duty cycle, but it was not observed (FIGS. 4B and 12A and 12B). As a result, integral windup was not observed and no compensation is needed, though there would be simple techniques to do so if required. Similarly, our controller did not perform the most aggressive actions possible for fast operation: control inputs never reached maximum power, and so the actuator necessarily responded slower than could have otherwise been possible. Many improvements can be made for better performance, including sliding mode control or other model-based methods. However, the controller validates the concept while highlighting the benefits of active cooling.

Robot design: The soft robotic walker was designed with two 60-semiconductor LCE-TED actuators with their ends mounted 90 degrees apart in a laser cut acrylic frame. 150 micrometer thick jagged copper feet were adhered using Sil-poxy onto the ends of the walker for directional dependent friction. In its rest state the device is 65 mm high and 92 mm wide. Each limb was actuated with a 3.0 V power source. The actuation times were left limb+3 V, right limb−3 V for 45 s, then left limb 0 V, Right limb+3 V for 10 s, followed by a cool down period of about 6:30.

The present invention is directed to the following aspects:

Aspect 1. A stretchable and flexible thermoelectric device comprising: a substrate comprising an array of semiconductors in electrical communication via a plurality of liquid metal interconnects, and coated on at least a portion thereof with opposing liquid crystal elastomer layers comprising a reaction product of a reaction mixture comprising a mesogenic group, a spacer, a crosslinker, and a photoinitiator, wherein the opposed liquid crystal elastomer layers alternately heat and cool to achieve cyclical bending actuation when voltage is applied to the device.

Aspect 2. The device according to aspect 1, wherein the substrate comprises a polyacrylate comprising a reaction product of an epoxy aliphatic acrylate and an aliphatic urethane acrylate.

Aspect 3. The device according to any of the preceding aspects, wherein the liquid metal interconnects comprise eutectic gallium-indium (EGaIn).

Aspect 4. The device according to any of the preceding aspects, wherein the semiconductors comprise n-type bismuth telluride (Bi2Te3) semiconductor and p-type bismuth telluride (Bi2Te3) semiconductor in P-N configuration.

Aspect 5. The device according to any of the preceding aspects, wherein the mesogen is 4-bis-[4-(3-acryloyloxypropypropyloxy) benzoyloxy]-2-methylbenzene, the spacer is 2,2-(ethylenedioxy) diethanethiol (EDDET), the crosslinker is pentaerythritol tetrakis (3-mercaptopropionate) (PETMP), and the photoinitiator is ((2-hydroxyethoxy)-2-methylpropiophenone).

Aspect 6. The device according to any of the preceding aspects comprising an encapsulating layer coated on at least a portion of the opposing liquid crystal elastomer layers.

Aspect 7. The device according to any of the preceding aspects, wherein the encapsulating layer comprises a polyacrylate comprising a reaction product of an epoxy aliphatic acrylate and an aliphatic urethane acrylate.

Aspect 8. The device according to any of the preceding aspects comprising an adhesive layer coated on at least a portion of the encapsulating layer.

Aspect 9. The device according to any of the preceding aspects, wherein the adhesive layer comprises a flexible epoxy.

Aspect 10. The device according to any of the preceding aspects configured to cause cyclical bending actuation in response to voltage-controlled Peltier activation.

Aspect 11. The device according to any of the preceding aspects characterized by at least one of a bending angle range from −45 degrees to 45 degrees when a voltage is applied; a bending angle range from −30 degrees to 30 degrees when a voltage is applied; a bending angle range from −15 degrees to 15 degrees when a voltage is applied; a bending angle range from −5 degrees to 5 degrees when a voltage is applied, wherein the bending angle is the angle between an end of the device when no voltage is applied and the end of the device when voltage is applied; and an angular velocity of 0.1-5 degrees/second when a voltage is applied; an angular velocity of 0.1-1 degrees/second when a voltage is applied; an angular velocity of 0.5-5 degrees/second when a voltage is applied; and an angular velocity of 1-5 degrees/second when a voltage is applied.

Aspect 12. The device according to any of the preceding aspects, wherein the device is configured to heat and cool the top encapsulating layer and bottom encapsulating layer at the same time when the input voltage is reversed from positive to negative.

Aspect 13. The device according to any of the preceding aspects, wherein the device is a regenerative energy harvesting device configured to covert a portion of heat applied to the device into voltage.

Aspect 14. A single-degree-of-freedom robotic limb comprising the device according to any of the preceding aspects.

Aspect 15. A liquid crystal elastomer-thermoelectric device walker comprising two devices according to any of the preceding aspects oriented 45-90 degrees apart and connected at an end, such as oriented 60-90 degrees apart, oriented 45-60 degrees apart, oriented 90 degrees apart, oriented 45 degrees apart, and oriented 60 degrees apart.

Aspect 16. The device according to any of the preceding aspects, wherein the liquid crystal elastomer layers have a thickness from 0.5 mm to 2 mm, such as 0.5-1 mm and 1-2 mm.

Aspect 17. The device according to any of the preceding aspects, wherein the array of semiconductors comprises 60-90 semiconductors.

Aspect 18. The device according to any of the preceding aspects, wherein the opposing liquid crystal elastomer layers are the same or different.

All documents cited herein are incorporated herein by reference, but only to the extent that the incorporated material does not conflict with existing definitions, statements, or other documents set forth herein. To the extent that any meaning or definition of a term in this document conflicts with any meaning or definition of the same term in a document incorporated by reference, the meaning or definition assigned to that term in this document shall govern. The citation of any document is not to be construed as an admission that it is prior art with respect to this application.

While particular embodiments have been illustrated and described, it would be obvious to those skilled in the art that various other changes and modifications may be made without departing from the spirit and scope of the invention. Those skilled in the art will recognize or be able to ascertain using no more than routine experimentation, numerous equivalents to the specific apparatuses and methods described herein, including alternatives, variants, additions, deletions, modifications and substitutions. This application including the appended claims is therefore intended to cover all such changes and modifications that are within the scope of this application.

The attached Appendix provides additional details regarding the Figures.

### REFERENCES

1. Ula, S. W. et al. Liquid crystal elastomers: An introduction and review of emerging technologies. Liq. Cryst. Rev. 6, 78-107 (2018).
2. Qian, X. et al. Untethered Recyclable Tubular Actuators with Versatile Locomotion for Soft Continuum Robots. Adv. Mater. 30, (2018).
3. Kotikian, A., Truby, R. L., Boley, J. W., White, T. J. & Lewis, J. A. 3D Printing of Liquid Crystal Elastomeric Actuators with Spatially Programed Nematic Order. Adv. Mater. 30, (2018).
4. Wang, Y. et al. Electrically Controlled Soft Actuators with Multiple and Reprogrammable Actuation Modes. Adv. Intell. Syst. 2, 1900177 (2020).
5. Torras, N., Zinoviev, K. E., Esteve, J. & Sánchez-Ferrer, A. Liquid-crystalline elastomer micropillar array for haptic actuation. J. Mater. Chem. C 1, 5183-5190 (2013).
6. Ford, M. J. et al. A multifunctional shape-morphing elastomer with liquid metal inclusions. Proc. Natl. Acad. Sci. U. S. A. 116, 21438-21444 (2019).
7. Kotikian, A. et al. Untethered soft robotic matter with passive control of shape morphing and propulsion. Sci. Robot. 4, 1-11 (2019).
8. Shen, Z., Chen, F., Zhu, X., Yong, K. T. & Gu, G. Stimuli-responsive functional materials for soft robotics. J. Mater. Chem. B 8, 8972-8991 (2020).
9. Ambulo, C. P. et al. Four-dimensional Printing of Liquid Crystal Elastomers. ACS Appl. Mater. Interfaces 9, 37332-37339 (2017).
10. Rich, S. I., Wood, R. J. & Majidi, C. Untethered soft robotics. Nat. Electron. 1, 102-112 (2018).
11. Roach, D. J. et al. Long Liquid Crystal Elastomer Fibers with Large Reversible Actuation Strains for Smart Textiles and Artificial Muscles. ACS Appl. Mater. Interfaces 11, 19514-19521 (2019).
12. Boothby, J. M. et al. An Untethered Soft Robot Based on Liquid Crystal Elastomers. Soft Robot. 00, 1-9 (2021).
13. He, Q. et al. Electrically controlled liquid crystal elastomer-based soft tubular actuator with multimodal actuation. Sci. Adv. 5, 1-7 (2019).
14. Li, S. et al. Digital light processing of liquid crystal elastomers for self-sensing artificial muscles. Sci. Adv. 7, (2021).
15. Ware, T. H., McConney, M. E., Wie, J. J., Tondiglia, V. P. & White, T. J. Voxelated liquid crystal elastomers. Science (80-.). 347, 982-984 (2015).
16. Zhang, C. et al. 4D Printing of a Liquid Crystal Elastomer with a Controllable Orientation Gradient. ACS Appl. Mater. Interfaces 11, 44774-44782 (2019).
17. Kent, T. A., Ford, M. J., Markvicka, E. J. & Majidi, C. Soft actuators using liquid crystal elastomers with encapsulated liquid metal joule heaters. Multifunct. Mater. 3, 025003 (2020).
18. Yuan, C. et al. 3D printed reversible shape changing soft actuators assisted by liquid crystal elastomers. Soft Matter 13, 5558-5568 (2017).
19. Ford, M. J., Palaniswamy, M., Ambulo, C. P., Ware, T. H. & Majidi, C. Size of liquid metal particles influences actuation properties of a liquid crystal elastomer composite. Soft Matter 16, 5878-5885 (2020).
20. Kotikian, A. et al. Innervated, Self-Sensing Liquid Crystal Elastomer Actuators with Closed Loop Control. Adv. Mater. 33, 2101814 (2021).
21. Ambulo, C. P., Ford, M. J., Searles, K., Majidi, C. & Ware, T. H. 4D-Printable Liquid Metal-Liquid Crystal Elastomer Composites. ACS Appl. Mater. Interfaces 13, 12805-12813 (2021).
22. Minori, A. F. et al. Reversible actuation for self-folding modular machines using liquid crystal elastomer. Smart Mater. Struct. 29, 105003 (2020).
23. Wang, C. et al. Soft Ultrathin Electronics Innervated Adaptive Fully Soft Robots. Adv. Mater. 30, 1706695 (2018).
24 Liu, H. et al. An Electrically Actuated Soft Artificial Muscle Based on a High-Performance Flexible Electrothermal Film and Liquid-Crystal Elastomer. ACS Appl. Mater. Interfaces 12, 56338-56349 (2020).
25. Lu, H. et al. Biomimetic Prosthetic Hand Enabled by Liquid Crystal Elastomer Tendons. Micromachines 2021, Vol. 12, Page 736 12, 736 (2021).
26. He, Q., Wang, Z., Wang, Y., Song, Z. & Cai, S. Recyclable and Self-Repairable Fluid-Driven Liquid Crystal Elastomer Actuator. ACS Appl. Mater. Interfaces 12, 35464-35474 (2020).
27. Zeng, H., Wani, O. M., Wasylczyk, P., Kaczmarek, R. & Priimagi, A Self-Regulating Iris Based on Light-Actuated Liquid Crystal Elastomer. Adv. Mater. 29, 1701814 (2017).
28. Wang, Z., Li, K., He, Q. & Cai, S. A Light-Powered Ultralight Tensegrity Robot with High Deformability and Load Capacity. Adv. Mater. 31, 1806849 (2019).
29. Rog6z, M., Dradrach, K., Xuan, C. & Wasylczyk, P. A Millimeter-Scale Snail Robot Based on a Light-Powered Liquid Crystal Elastomer Continuous Actuator. Macromol. Rapid Commun. 40, 1900279 (2019).
30. Wang, X. et al. A study of the microwave actuation of a liquid crystalline elastomer. Soft Matter 16, 7332-7341 (2020).
31. Liu, J. et al. Shaping and Locomotion of Soft Robots Using Filament Actuators Made from Liquid Crystal Elastomer-Carbon Nanotube Composites. Adv. Intell. Syst. 2, 1900163 (2020).
32. Schuhladen, S. et al. Iris-like tunable aperture employing liquid-crystal elastomers. Adv. Mater. 26, 7247-7251 (2014).
33. Wang, M. et al. Liquid Crystal Elastomer Electric Locomotives. ACS Macro Lett. 9, 860-865 (2020).
34. He, Q. et al. Electrospun liquid crystal elastomer microfiber actuator. Sci. Robot. 6, (2021).
35. Huber, J. E., Fleck, N. A. & Ashby, M. F. The selection of mechanical actuators. Proc. R. Soc. London. Ser. A Math. Phys. Eng. Sci. 453, 2185-2205 (1997).
36. Whitesides, G. M. Soft Robotics. Angew. Chemie—Int. Ed. 57, 4258-4273 (2018).
37. Kim, C. S. et al. Self-Powered Wearable Electrocardiogramaing a Wearable Thermoelectric Power Generator. ACS Energy Lett. 3, 501-507 (2018).
38. Zadan, M., Malakooti, M. H. & Majidi, C. Soft and Stretchable Thermoelectric Generators Enabled by Liquid Metal Elastomer Composites. ACS Appl. Mater. Interfaces 12, 17921-17928 (2020).
39. Zadan, M., Chiew, C., Majidi, C. & Malakooti, M. H. Liquid metal architectures for soft and wearable energy harvesting devices. Multifunct. Mater. 4, (2021).
40. Kim, S. J. et al. High-Performance Flexible Thermoelectric Power Generator Using Laser Multiscanning Lift-Off Process. ACS Nano 10, 10851-10857 (2016).
41. Suarez, F. et al. Flexible thermoelectric generator using bulk legs and liquid metal interconnects for wearable electronics. Appl. Energy 202, 736-745 (2017).
42. Jeong, S. H. et al. Stretchable Thermoelectric Generators Metallized with Liquid Alloy. ACS Appl. Mater. Interfaces 9, 15791-15797 (2017).
43. Petsch, S. et al. Smart artificial muscle actuators: Liquid crystal elastomers with integrated temperature feedback. Sensors Actuators, A Phys. 231, 44-51 (2015).
44. Wertz, A., Sabelhaus, A. P. & Majidi, C. Trajectory Optimization for Thermally-Actuated Soft Planar Robot Limbs. arXiv: 2110.09474 (2021).
45. Ianagui, A. & Tannuri, E. A. A sliding mode torque and position controller for an antagonistic SMA actuator. Mechatronics 30, 126-139 (2015).
46. Moallem, M. & Tabrizi, V. A. Tracking control of an antagonistic shape memory alloy actuator pair. IEEE Trans. Control Syst. Technol. 17, 184-190 (2009).
47. Patel, D. K. et al. Highly Stretchable and UV Curable Elastomers for Digital Light Processing Based 3D Printing. Adv. Mater. 29, 1606000 (2017).
48. Lee, M.-Y., Seo, J.-H., Lee, H.-S. & Garud, K. S. Power Generation, Efficiency and Thermal Stress of Thermoelectric Module with Leg Geometry, Material, Segmentation and Two-Stage Arrangement. Symmetry 2020, Vol. 12, Page 786 12, 786 (2020).
49. Carreon-Bautista, S., Eladawy, A., Nader Mohieldin, A. & Sanchez-Sinencio, E. Boost converter with dynamic input impedance matching for energy harvesting with multi-array thermoelectric generators. IEEE Trans. Ind. Electron. 61, 5345-5353 (2014).
50. Yakacki, C. M. et al. Tailorable and programmable liquid-crystalline elastomers using a two-stage thiol-acrylate reaction. RSC Adv. 5, 18997-19001 (2015).
51. Song, S., Joshi, S. & Paik, J. CMOS-Inspired Complementary Fluidic Circuits for Soft Robots. Adv. Sci. 2100924 (2021) doi: 10.1002/ADVS.202100924.
52. Sitti, M. Physical intelligence as a new paradigm. Extrem. Mech. Lett. 46, 101340 (2021).
53. Yan, Y. et al. Artificial Phototropic Systems for Enhanced Light Harvesting Based on a Liquid Crystal Elastomer. Adv. Intell. Syst. 3, 2000234 (2021).
54. Guo, H., Saed, M. O. & Terentjev, E. M. Heliotracking Device using Liquid Crystalline Elastomer Actuators. Adv. Mater. Technol. 6, 1-9 (2021).
55. Bartlett, M. D. et al. High thermal conductivity in soft elastomers with elongated liquid metal inclusions. Proc. Natl. Acad. Sci. U. S. A. 114, 2143-2148 (2017).
56. Malakooti, M. H., Zadan, M., Kazem, N. & Majidi, C. Liquid metal composites for flexible thermoelectric energy harvesting. 12 (2021) doi: 10.1117/12.2582867.
57. Malakooti, M. H. et al. Liquid Metal Supercooling for Low-Temperature Thermoelectric Wearables. Adv. Funct. Mater. 29, 1906098 (2019).
58. Patterson, Z. J., Sabelhaus, A. P., Chin, K., Hellebrekers, T. & Majidi, C. An untethered brittle star-inspired soft robot for closed-loop underwater locomotion. IEEE Int. Conf. Intell. Robot. Syst. 8758-8764 (2020) doi: 10.1109/IROS45743.2020.9341008.
59. U.S. Patent Publication No. 20220098461.
60. Zadan, M., Patel, D. K., Sabelhaus, A. P., Liao, J., Wertz A., Yao, L., and Majidi, C. Liquid crystal elastomers with integrated soft thermoelectrics for shape memory actuation and energy harvesting. Adv. Mater. 2002, 34, 2200857 doi: 10.1002/adma.202200857.

What is claimed is:

1. A stretchable and flexible thermoelectric device comprising: a substrate comprising an array of semiconductors in electrical communication via a plurality of liquid metal interconnects, and coated on at least a portion thereof with opposing liquid crystal elastomer layers comprising a reaction product of a reaction mixture comprising a mesogenic group, a spacer, a crosslinker, and a photoinitiator, wherein the opposed liquid crystal elastomer layers alternately heat and cool to achieve cyclical bending actuation when voltage is applied to the device.

2. The device of claim 1, wherein the substrate comprises a polyacrylate comprising a reaction product of an epoxy aliphatic acrylate and an aliphatic urethane acrylate.

3. The device of claim 1, wherein the liquid metal interconnects comprise eutectic gallium-indium (EGaIn).

4. The device of claim 1, wherein the semiconductors comprise n-type bismuth telluride (Bi₂Te₃) semiconductor and p-type bismuth telluride (Bi₂Te₃) semiconductor in P-N configuration.

5. The device of claim 1, wherein the mesogen is 4-bis-[4-(3-acryloyloxypropypropyloxy) benzoyloxy]-2-methylbenzene, the spacer is 2,2-(ethylenedioxy) diethanethiol (EDDET), the crosslinker is pentaerythritol tetrakis (3-mercaptopropionate) (PETMP), and the photoinitiator is ((2-hydroxyethoxy)-2-methylpropiophenone).

6. The device of claim 1 comprising an encapsulating layer coated on at least a portion of the opposing liquid crystal elastomer layers.

7. The device of claim 6, wherein the encapsulating layer comprises a polyacrylate comprising a reaction product of an epoxy aliphatic acrylate and an aliphatic urethane acrylate.

8. The device of claim 6 comprising an adhesive layer coated on at least a portion of the encapsulating layer.

9. The device of claim 8, wherein the adhesive layer comprises a flexible epoxy.

10. The device of claim 1 configured to cause cyclical bending actuation in response to voltage-controlled Peltier activation.

11. The device of claim 10 characterized by at least one of
a bending angle range from −30 degrees to 30 degrees when a voltage is applied; and
an angular velocity of 0.1-5 degrees/second when a voltage is applied.

12. The device of claim 6, wherein the device is configured to heat and cool the top encapsulating layer and bottom encapsulating layer at the same time when the input voltage is reversed from positive to negative.

13. The device of claim 1, wherein the device is a regenerative energy harvesting device configured to covert a portion of heat applied to the device into voltage.

14. A single-degree-of-freedom robotic limb comprising the device of claim 1.

15. A liquid crystal elastomer-thermoelectric device walker comprising two devices of claim 1 oriented 90 degrees apart and connected at an end.
